(19) United States
(12) Patent Application Publication
(10) Pub. No.: US 2025/0349369 A1
(43) Pub. Date: Nov. 13, 2025

(54) MEMORY CONTROLLERS, MEMORY SYSTEMS, AND CONTROL METHODS THEREOF

(71) Applicant: Yangtze Memory Technologies Co., Ltd., Wuhan (CN)

(72) Inventor: Teng Zhou, Wuhan (CN)

(21) Appl. No.: 18/816,752

(22) Filed: Aug. 27, 2024

(30) Foreign Application Priority Data
May 8, 2024 (CN) 202410565239.7

(51) Int. Cl. G11C 16/34; G06F 12/02; G11C 11/56; G11C 16/04; G11C 16/26

(52) U.S. Cl. CPC G11C 16/3404; G06F 12/0246; G11C 11/5642; G11C 11/5671; G11C 16/0483; G11C 16/26

(57) ABSTRACT

Examples of the present disclosure disclose a memory controller, a memory system, and a control method thereof. The memory controller is configured to: control a memory device to perform a read operation with a first read voltage corresponding to a first data state of a memory cell; obtain the first number of memory cells with a threshold voltage being less than or equal to the first read voltage, and obtain the second number of memory cells with a threshold voltage being greater than the first read voltage; determine a difference between the second number and the first number; and acquire a voltage offset value from a mapping table according to the difference.

### CROSS-REFERENCE TO RELATED APPLICATIONS

This application claims priority to and the benefit of Chinese Patent Application 202410565239.7, filed on May 8, 2024, which is hereby incorporated by reference in its entirety.

### TECHNICAL FIELD

Examples of the present disclosure relate to the field of semiconductor technologies, and in particular, to a memory controller, a memory system and a control method thereof, and a readable storage medium.

### BACKGROUND

A memory device is a storage apparatus used to keep information in modern information technologies. Some semiconductor memories, such as a non-volatile memory, gradually become mainstream products in the memory market due to their high storage density, controllable production cost, suitable program and erase speeds, and retention property.

### BRIEF DESCRIPTION OF THE DRAWINGS

FIG. 1 is a schematic diagram illustrating an example system according to examples of the present disclosure;

FIG. 2A is a schematic diagram illustrating an example memory card according to examples of the present disclosure;

FIG. 2B is a schematic diagram illustrating an example solid-state drive according to examples of the present disclosure;

FIG. 3 is a schematic diagram illustrating an example memory device according to examples of the present disclosure;

FIG. 4 is a schematic diagram illustrating an example cross section of a memory cell array according to examples of the present disclosure;

FIG. 5 is a schematic diagram illustrating another example memory device according to examples of the present disclosure;

FIG. 6 is a schematic diagram illustrating an example memory system according to examples of the present disclosure;

FIG. 7 is a schematic diagram of an example operation according to examples of the present disclosure;

FIG. 8 is a schematic diagram illustrating a threshold voltage distribution according to examples of the present disclosure;

FIG. 9 is a schematic diagram illustrating a read retry table according to examples of the present disclosure;

FIG. 10 to FIG. 14 are schematic diagrams illustrating read information according to examples of the present disclosure;

FIG. 15 is a schematic diagram illustrating a mapping table according to examples of the present disclosure;

FIG. 16 is a schematic diagram of an operation according to examples of the present disclosure;

FIG. 17 is a schematic diagram illustrating another mapping table according to examples of the present disclosure;

FIG. 18 is a schematic diagram illustrating an association coefficient according to examples of the present disclosure;

FIG. 19 is a schematic diagram of another operation according to examples of the present disclosure; and

FIG. 20 is a schematic diagram of an example method for controlling a memory system according to examples of the present disclosure.

### DETAILED DESCRIPTION

Example implementations disclosed by the present disclosure will be described below in more details with reference to the drawings. Although the example implementations of the present disclosure are shown in the drawings, it is to be understood that the present disclosure may be implemented in various forms and should not be limited by the specific implementations set forth herein. Rather, these implementations are provided for a more thorough understanding of the present disclosure, and to fully convey a scope disclosed by the present disclosure to those skilled in the art.

In the following description, numerous specific details are given in order to provide a more thorough understanding of the present disclosure. However, it is apparent to those skilled in the art that the present disclosure may be practiced without one or more of these details. In other examples, in order to avoid confusing with the present disclosure, some technical features well-known in the art are not described; that is, not all features of actual examples are described here, and well-known functions and structures are not described in detail.

It is to be understood that when an element or a layer is referred to as being “on”, “adjacent to”, “connected to”, or “coupled to” other elements or layers, it may be directly on, adjacent to, connected to, or coupled to the elements or layers, or intervening elements or layers may be present. In contrast, when an element is referred to as being “directly on”, “directly adjacent to”, “directly connected to”, or “directly coupled to” other elements or layers, no intervening elements or layers are present.

The terms used herein are only intended to describe the particular examples, and are not used as limitations of the present disclosure. As used herein, unless otherwise indicated expressly in the context, “a”, “an” and “the” in a singular form are also intended to comprise a plural form. It should also be understood that terms “consist of” and/or “comprise”, when used in this specification, determine the presence of the described features, integers, steps, operations, elements and/or components, but do not preclude the presence or addition of one or more of other features, integers, steps, operations, elements, components, and/or groups. As used herein, the term “and/or” comprises any or all combinations of the listed relevant items.

It is to be understood that references to “some examples” or “an example” throughout this specification mean that particular features, structures, or characteristics related to the examples or example are comprised in at least one example of the present disclosure. Therefore, “in some examples” or “in an example” presented everywhere throughout this specification does not necessarily refer to the same example. Furthermore, these particular features, structures, or characteristics may be incorporated in one or more examples in any suitable manner. It is to be understood that, in various examples of the present disclosure, the sequence number of each process does not mean the sequence of execution. The execution sequence of each process should be determined by its functions and internal logic, which should not constitute any limitation on the implementation process of the examples of the present disclosure.

Due to increasingly high requirements for a storage apparatus, there is much room for improvements in the memory device and a system thereof.

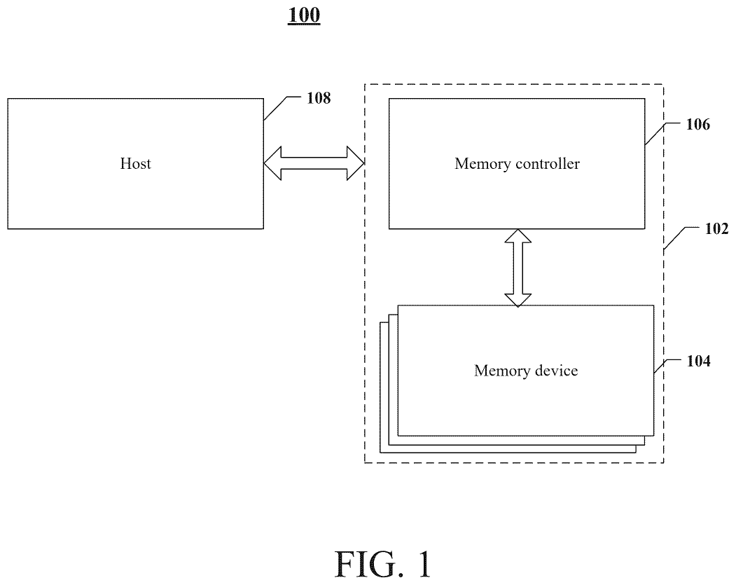

FIG. 1 illustrates a block diagram of an example system 100 having a memory device according to some aspects of the present disclosure. The system 100 may be a mobile phone, a desktop computer, a laptop computer, a tablet computer, a vehicle computer, a gaming console, a printer, a positioning apparatus, a wearable electronic apparatus, a smart sensor, a virtual reality (VR) apparatus, an augmented reality (AR) apparatus, or any other suitable electronic apparatuses having memories therein. As shown in FIG. 1, the system 100 may comprise a host 108 and a memory system 102, wherein the memory system 102 has one or more memory devices 104 and a memory controller 106. The host 108 may be a processor (e.g., a central processing unit (CPU)) or a system on chip (SOC) (e.g., an application processor (AP)) of an electronic apparatus. The host 108 may be configured to send or receive data to or from memory devices 104. The memory device 104 may comprise, but is not limited to, a 2D or 3D Not-And (NAND) memory, a NOR memory, a Ferroelectric Random Access Memory (FRAM), a Magnetic Random Access Memory (MRAM), a Phase-Change Memory (PCM), and a Resistive Random Access Memory (RRAM), etc.

According to some implementations, the memory controller 106 is coupled to the memory device 104 and the host 108, and configured to control the memory device 104. The memory controller 106 can manage data stored in the memory device 104 and communicate with the host 108. In some implementations, the memory controller 106 is designed for operating in a low duty-cycle environment, such as a Secure Digital (SD) card, a Compact Flash (CF) card, a Universal Serial Bus (USB) flash drive, or other media for use in electronic apparatuses, such as a personal computer, a digital camera, and a mobile phone, etc. In some implementations, the memory controller 106 is designed for operating in a high duty-cycle environment, such as an SSD or embedded Multi-Media Card (eMMC) that is used as a data memory for a mobile apparatus such as a smartphone, a tablet computer, and a laptop computer, etc., and an enterprise memory array.

The memory controller 106 may be configured to control operations of the memory device 104, such as read, erase, and program operations. The memory controller 106 may be further configured to manage various functions with respect to data stored or to be stored in the memory device 104, comprising, but not limited to, bad-block management, garbage collection, logical-to-physical address conversion, and wear leveling, etc. In some implementations, the memory controller 106 is further configured to process an Error Correction Code (ECC) with respect to data read from or written to the memory device 104. The memory controller 106 may also perform any other suitable functions, e.g., formatting the memory device 104. The memory controller 106 may communicate with an external apparatus (e.g., the host 108) according to a particular communication protocol. For example, the memory controller 106 may communicate with the external apparatus through at least one of various interface protocols, such as a USB protocol, an MMC protocol, a Peripheral Component Interconnection (PCI) protocol, a PCI-Express (PCI-E) protocol, an Advanced Technology Attachment (ATA) protocol, a Serial-ATA protocol, a Parallel-ATA protocol, a Small Computer Small Interface (SCSI) protocol, an Enhanced Small Disk Interface (ESDI) protocol, an Integrated Drive Electronics (IDE) protocol, and a Firewire protocol, etc.

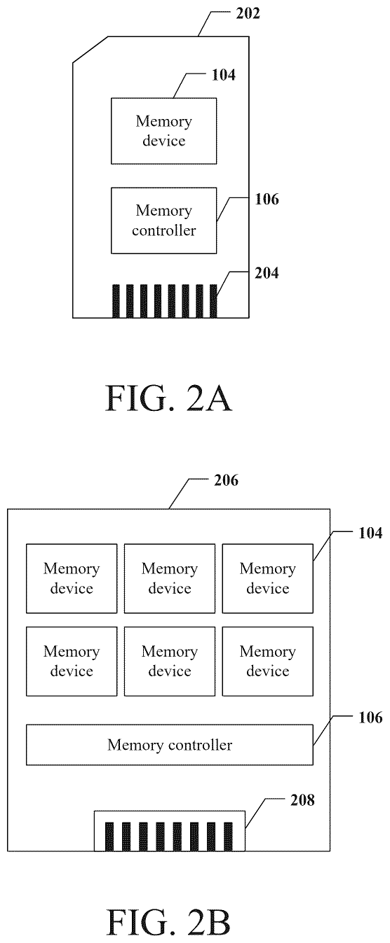

The memory controller 106 and one or more memory devices 104 can be integrated into various types of storage apparatuses, e.g., be comprised in the same package (such as a Universal Flash Storage (UFS) package or an eMMC package). That is, the memory system 102 can be implemented and packaged into different types of end electronic products. In an example shown in FIG. 2A, the memory controller 106 and a single memory device 104 may be integrated into a memory card 202. The memory card 202 may comprise a PC card (Personal Computer Memory Card International Association (PCMCIA)), a CF card, a Smart Media (SM) card, a memory stick, a multimedia card (MMC, RS-MMC, MMCmicro), an SD card (SD, miniSD, microSD, SDHC), and a UFS, etc. The memory card 202 may further comprise a memory card connector 204 coupling the memory card 202 with a host (e.g., the host 108 in FIG. 1). In another example shown in FIG. 2B, the memory controller 106 and the plurality of memory devices 104 may be integrated into an SSD 206. The SSD 206 may further comprise an SSD connector 208 coupling the SSD 206 with a host (e.g., the host 108 in FIG. 1). In some implementations, at least one of a storage capacity or an operation speed of the SSD 206 is greater than that of the memory card 202.

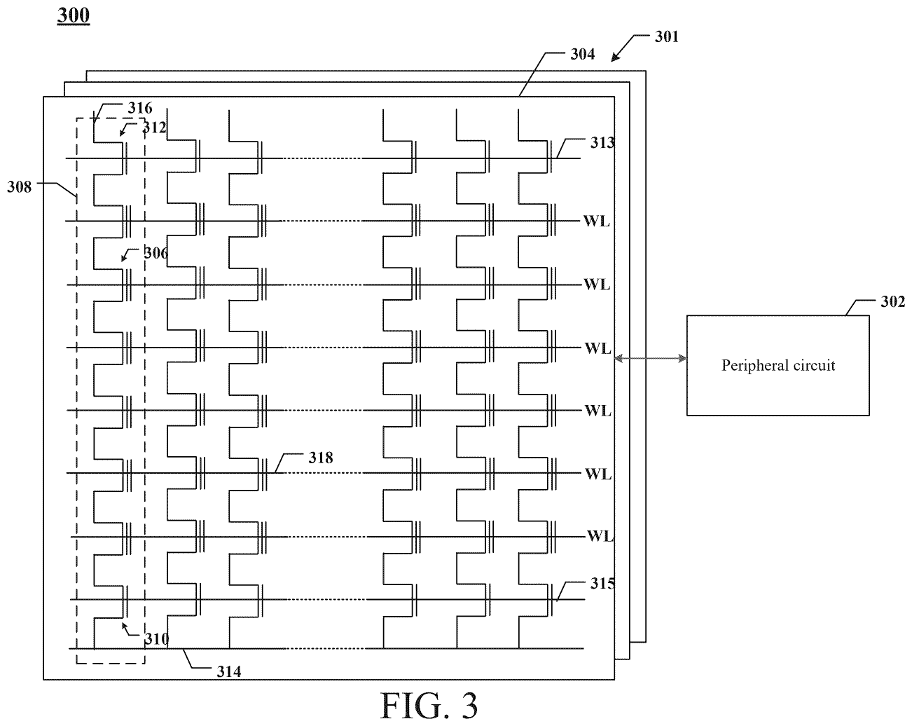

The memory device 104 in the examples of the present disclosure is explained and illustrated using the Not-And (NAND) memory as an example, and the memory device 104 in the examples of the present disclosure may comprise other memories. FIG. 3 illustrates a schematic circuit diagram of an example memory device 300 comprising a peripheral circuit according to some aspects of the present disclosure. The memory device 300 may be an example of the memory device 104 in FIG. 1. The memory device 300 may comprise a memory cell array 301 and a peripheral circuit 302 coupled to the memory cell array 301. An illustration is performed with an example in which the memory cell array 301 is a three-dimensional NAND memory cell array, wherein memory cells 306 are provided in an array of NAND memory strings 308, and each NAND memory string 308 extends perpendicularly above a substrate (not shown). In some implementations, each NAND memory string 308 comprises a plurality of memory cells 306 coupled in series and stacked perpendicularly. Each memory cell 306 may maintain a continuous analog value, such as voltage or charge, which depends on the number of electrons trapped within a region of the memory cell 306. Each memory cell 306 may be a floating gate memory cell that comprises a floating gate transistor, or a charge trap memory cell that comprises a charge trap transistor.

In some implementations, each memory cell 306 is a Single Level Cell (SLC) that has two possible memory states and thus can store one bit of data. For example, a first memory state “0” may correspond to a first voltage range, and a second memory state “1” may correspond to a second voltage range. In some implementations, each memory cell 306 is a Multiple Level Cell (MLC) capable of storing more than a single bit of data in more than four memory states. For example, the MLC can store two bits per cell, three bits per cell (also referred to as a Triple Level Cell (TLC)), or four bits per cell (also referred to as a Quad Level Cell (QLC)). Each MLC is programmable to adopt a range of possible nominal memory values. In one example, if each MLC stores two bits of data, the MLC is programmable to write one of three possible nominal memory values to the cell, while a fourth nominal memory value other than the three nominal memory values may be used to represent an erase state.

As shown in FIG. 3, each NAND memory string 308 may comprise a bottom select gate (BSG) 310 at its source terminal and a top select gate (TSG) 312 at its drain terminal. The BSG 310 and the TSG 312 may be configured to activate a selected NAND memory string 308 during read and program operations. In some implementations, sources of the NAND memory strings 308 in the same memory block 304 are coupled through the same source line (SL) 314 (e.g., a common SL). In other words, according to some implementations, all the NAND memory strings 308 in the same memory block 304 have an array common source (ACS). According to some implementations, the TSG 312 of each NAND memory string 308 is coupled to a respective bit line (BL) 316 which data can be read from or written to via an output bus (not shown). In some implementations, each NAND memory string 308 is configured to be selected or unselected by applying a select voltage (e.g., above a threshold voltage of a transistor having the TSG 312) or an unselect voltage (e.g., 0 V) to the respective TSG 312 via one or more TSG lines 313 and/or by applying a select voltage (e.g., above a threshold voltage of a transistor having the BSG 310) or an unselect voltage (e.g., 0 V) to the respective BSG 310 via one or more BSG lines 315.

As shown in FIG. 3, the NAND memory strings 308 can be organized into a plurality of memory blocks 304, and each of the memory blocks 304 may have a common source line 314 (e.g., coupled to the ground). In some implementations, each memory block 304 is a basic data unit for the erase operation, i.e., all the memory cells 306 on the same memory block 304 are erased at the same time. In order to erase the memory cells 306 in a selected memory block, the source line 314 coupled to the selected memory block and unselected memory blocks that are in the same plane as the selected memory block can be biased with an erase voltage (Vers) (such as a high positive voltage (e.g., 20 V or higher)). It is to be understood that in some examples, the erase operation may be performed at a half memory block level, a quarter memory block level, or a level having any suitable number of memory blocks or any suitable fractions of a memory block. The memory cells 306 of adjacent ones of the NAND memory strings 308 may be coupled through a word line 318, and a row of memory cells 306 selected by the word line 318 is affected by the read and program operations.

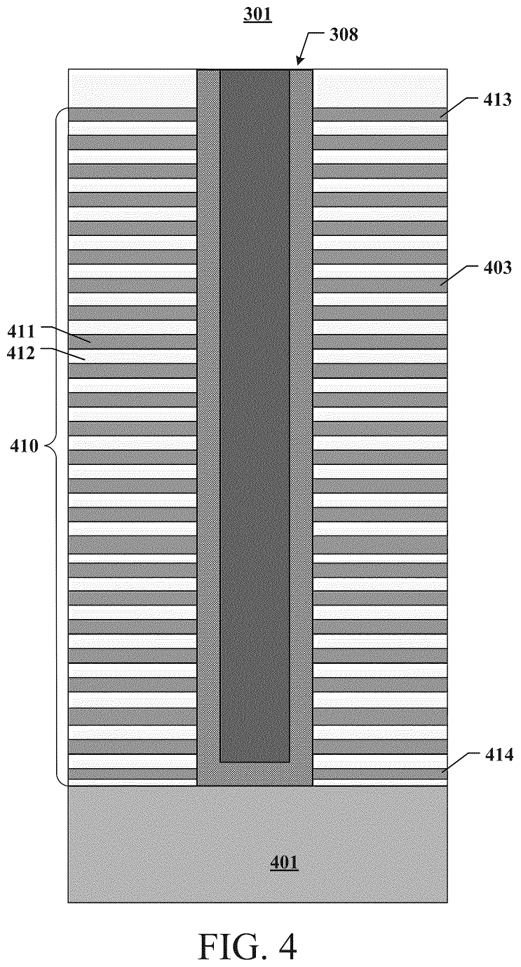

FIG. 4 illustrates a schematic cross-sectional view of the example memory cell array 301 comprising the NAND memory string 308 according to some aspects of the present disclosure. As shown in FIG. 4, the NAND memory string 308 may comprise a stack structure 410 which comprises a plurality of gate layers 411 and a plurality of insulation layers 412 that are disposed in a stack alternately and sequentially, and the memory string 308 penetrating through the gate layers 411 and the insulation layers 412 perpendicularly. The gate layers 411 and the insulation layers 412 may be stacked alternately, and two adjacent ones of the gate layers 411 are separated by one insulation layer 412. A number of pairs of the gate layers 411 and the insulation layers 412 in the stack structure 410 may determine the number of memory cells that are comprised in the memory cell array 301.

A constituent material of the gate layers 411 may comprise a conductive material. The conductive material comprises, but is not limited to, tungsten (W), cobalt (Co), copper (Cu), aluminum (Al), polysilicon, doped silicon, silicide, or any combination thereof. In some implementations, each gate layer 411 comprises a metal layer, e.g., a tungsten layer. In some implementations, each gate layer 411 comprises a doped polysilicon layer. Each gate layer 411 may comprise a control gate surrounding the memory cells. The gate layer 411 at the top of the stack structure 410 may extend laterally as a top select gate line; the gate layer 411 at the bottom of the stack structure 410 may extend laterally as a bottom select gate line; and the gate layers 411 that extend laterally between the top select gate line and the bottom select gate line may act as word line layers.

In some examples, the stack structure 410 may be disposed on a substrate 401. The substrate 401 may comprise silicon (e.g., monocrystalline silicon), silicon germanium (SiGe), gallium arsenide (GaAs), germanium (Ge), silicon on insulator (SOI), germanium on insulator (GOI), or any other suitable materials.

In some examples, the NAND memory string 308 comprises a channel structure that extends through the stack structure 410 vertically. In some implementations, the channel structure comprises a channel hole filled with (one or more) semiconductor materials (e.g., as a semiconductor channel) and (one or more) dielectric materials (e.g., as a memory film). In some implementations, the semiconductor channel comprises silicon, e.g., polysilicon. In some implementations, the memory film is a composite dielectric layer comprising a tunneling layer, a storage layer (also referred to as a “charge trap/storage layer”), and a barrier layer. The channel structure may have a cylindrical shape (e.g., a pillar shape). According to some implementations, the semiconductor channel, the tunneling layer, the storage layer, and the barrier layer are arranged radially from the center toward the outer surface of the pillar in this order. The tunneling layer may comprise silicon oxide, silicon oxynitride, or any combination thereof. The storage layer may comprise silicon nitride, silicon oxynitride, or any combination thereof. The barrier layer may comprise silicon oxide, silicon oxynitride, a high dielectric constant (high-k) dielectric, or any combination thereof. In an example, the memory film may comprise a composite layer of silicon oxide/silicon oxynitride/silicon oxide (ONO).

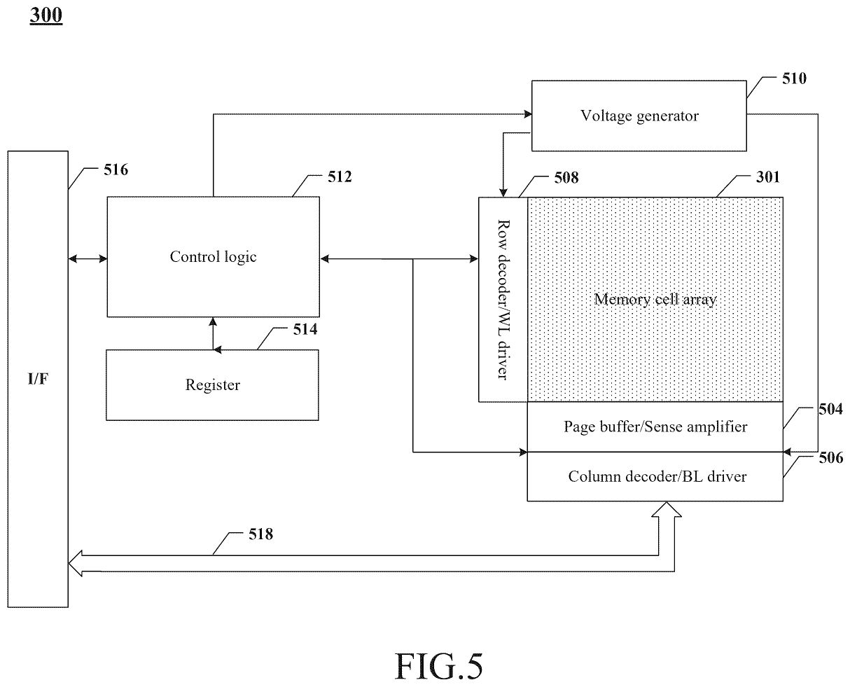

Referring back to FIG. 3, the peripheral circuit 302 may be coupled to the memory cell array 301 through the bit line 316, the word line 318, the source line 314, the BSG line 315 and the TSG line 313. The peripheral circuit 302 may comprise any suitable analog, digital, and hybrid signal circuits for facilitating operations of the memory cell array 301 by applying voltage signals and/or current signals to each target memory cell 306 and sensing voltage signals and/or current signals from each target memory cell 306 via the bit line 316, the word line 318, the source line 314, the BSG line 315, and the TSG line 313. The peripheral circuit 302 may comprise various types of peripheral circuits formed using a metal-oxide-semiconductor (MOS) technology. For example, FIG. 5 shows some example peripheral circuits. The peripheral circuit 302 comprises a page buffer/sense amplifier 504, a column decoder/bit line driver 506, a row decoder/word line driver 508, a voltage generator 510, a control logic 512, a register 514, an interface 516, and a data bus 518. It is to be understood that in some examples, an additional peripheral circuit not shown in FIG. 5 may also be comprised.

The page buffer/sense amplifier 504 may be configured to read and program (write) data from and to the memory cell array 301 according to control signals from the control logic 512. In one example, the page buffer/sense amplifier 504 may store program data (write data) to be programmed into the memory cell array 301. In another example, the page buffer/sense amplifier 504 may perform a program verify operation to ensure that data is properly programmed into the memory cells 306 that are coupled to the selected word line 318. In yet another example, the page buffer/sense amplifier 504 may also sense low power signals from the bit line 316 that represent data bits stored in the memory cells 306, and amplify a small voltage swing to a recognizable logic level during the read operation. The column decoder/bit line driver 506 may be configured to be controlled by the control logic 512 and select one or more NAND memory strings 308 by applying a bit line voltage generated from the voltage generator 510.

The row decoder/word line driver 508 may be configured to be controlled by the control logic 512, select/unselect the memory block 304 of the memory cell array 301, and select/unselect the word line 318 of the memory block 304. The row decoder/word line driver 508 may be further configured to drive the word line 318 using a word line voltage generated from the voltage generator 510. In some implementations, the row decoder/word line driver 508 may also select/unselect and drive the BSG line 315 and the TSG line 313. As described below in detail, the row decoder/word line driver 508 is configured to perform the program operation on the memory cells 306 that are coupled to (one or more) selected word lines 318. The voltage generator 510 may be configured to be controlled by the control logic 512 and generate the word line voltage (such as a read voltage, a program voltage, a pass voltage, a channel boost voltage, and a verify voltage), the bit line voltage, and a source line voltage to be supplied to the memory cell array 301.

The control logic 512 may be coupled to each peripheral circuit as described above and configured to control operations of each peripheral circuit. The register 514 may be coupled to the control logic 512 and comprise a state register, a command register, and an address register for storing state information, a command operation code (OP code), and a command address for controlling the operations of each peripheral circuit. The interface 516 may be coupled to the control logic 512, and act as a control buffer to buffer and relay control commands received from a host (not shown) to the control logic 512 and buffer and relay state information received from the control logic 512 to the host. The interface 516 may also be coupled to the column decoder/bit line driver 506 via the data bus 518 and act as a data I/O interface and a data buffer to buffer and relay the data to and from the memory cell array 301.

In some examples, the memory cell of the NAND memory may be classified into a single-layer memory cell (a one-bit memory cell), a double-layer memory cell (a two-bit memory cell), a three-layer memory cell (a three-bit memory cell), a four-layer memory cell (a four-bit memory cell), and a five-layer memory cell (a five-bit memory cell) according to a storage density. However, regardless of the single-layer memory cell or the multi-layer memory cell, the read operation thereof may be carried out in unit of pages. In an example, during the read operation, a read voltage is applied to the word line (e.g., the selected word line) coupled with a selected page in the memory device 104, and when the read voltage reaches a threshold voltage of a plurality of memory cells coupled with the selected word line, or a number of memory cells with a threshold voltage not reached by the read voltage is within a tolerance range, the read operation of the entire page is ended. The memory cell may be an n-bit memory cell which has 2ⁿ data states comprising an erase state, wherein n bits of memory data are read through 2ⁿ−1 read voltages. In an example, e.g., a first read voltage is between threshold voltages of the erase state and a first data state, when the first read voltage is applied to the word line, a memory cell in the erase state is on, a memory cell in the first data state is not on, and the erase state and the first data state are distinguished from each other and read out.

It is to be noted that during a process of the read operation, a memory cell with a target threshold voltage not reached by the read voltage is labeled as an error bit. In order to prevent a read error, an Error Correction Code (ECC) is introduced, such that all error bits in the read operation can be corrected when an error bit count is less than or equal to a maximum number of fail bits that can be corrected by the error correction code. As such, the data may be read properly.

In some examples, the host 108 sends a read command (or a read instruction, a read request) to the memory controller 106 according to a current user command requirement. The memory controller 106 transmits a read control command comprising information such as a logical address-physical address mapping table to the memory device 104 via the interface 516, to control the memory device 104 to perform the read operation for the memory cell corresponding to a respective physical address. The memory device 104 then sends read data to the memory controller 106 via the interface 516. The memory controller 106 feeds back the data to the host 108 via interfaces such as PCIe or SATA. In an example, the memory controller 106 sends the read control command to the control logic of the memory device via the interface 516, and the control logic applies a related operation voltage to the selected word line or bit line according to a related physical address, so as to perform the read operation on the corresponding memory cell. The control logic may control the voltage generator to generate the related operation voltage according to a related read voltage mapping table, which is decoded by the row decoder and then applied to the word line of the respective address, or applied to the bit line of the respective address by the column decoder.

In some other examples, a read error occurs when the memory device 104 reads the respective memory cell under the control of the memory controller 106. At this time, the memory controller 106 (or an error correction module in the memory controller 106) controls the memory device 104 to perform error correction in response to a read operation fail, wherein an error correction mode may comprise ECC error correction.

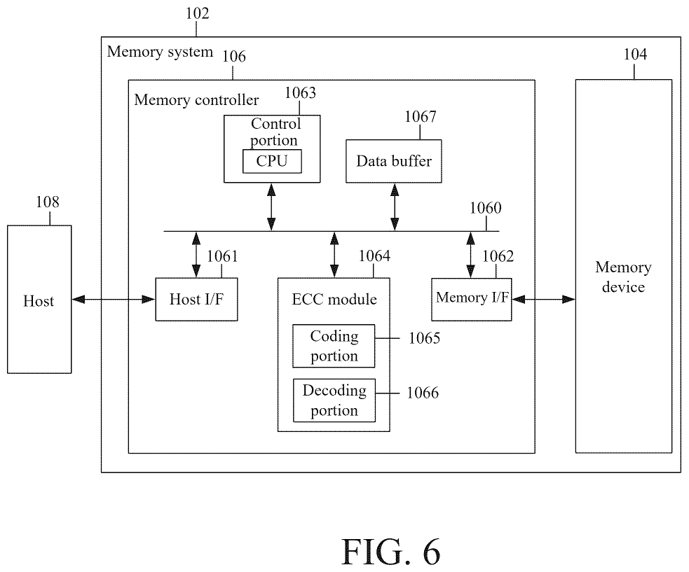

FIG. 6 provides a block diagram of employing the memory controller 106 to the memory system 102. Referring to FIG. 6, the memory system 102 comprises: the memory controller 106 and the memory device 104, wherein the memory controller 106 and the memory device 104 may be coupled in any suitable pattern. In the examples of the present disclosure, the memory controller 106 comprises a host I/F 1061, a memory I/F 1062, a control portion (control circuit) 1063, an error correction (ECC) module 1064, a data buffer 1067, and an internal bus 1060, wherein the error correction module 1064 comprises a coding portion 1065 and a decoding portion 1066. The host I/F 1061 outputs a command and user data (write data) etc. received from the host 108 to the internal bus 1060, and sends user data (read data) read from the memory device 104 and a response from the control portion 1063 etc. to the host 108.

The memory I/F controls processing of writing and reading user data etc. to and from the memory device 104 based on an instruction of the control portion 1063. The control portion 1063 overall controls the memory system 102, and is, for example, a central processing unit (CPU), or a micro-processing unit (MPU), etc. The control portion 1063 performs control according to a command in the case of receiving the command from the host 108 via the host I/F 1061. For example, the control portion 1063 instructs the memory I/F 1062 to write the user data and parity check data to the memory device 104 according to the command from the host 108. Furthermore, according to the command from the host 108, the control portion 1063 indicates to the memory I/F 1062 that the memory device 104 performs the program operation on the memory cells, and the memory device 104 updates the physical address-logical address mapping table after completing the program operation and gives feedback to the data buffer 1067 via the memory I/F 1062. Alternatively, according to the command from the host 108, the control portion 1063 indicates to the memory I/F 1062 that the memory device 104 reads the user data and the parity check data from the memory device 104.

The error correction module 1064 has the coding portion 1065 and the decoding portion 1066, and the coding portion 1065 may code the user data written to the same page and having a predetermined size to generate the parity check data, wherein coding may be performed based on program data to generate the parity check data. The parity check data is written to a page to which the user data has been written as a coding basis, and the decoding portion 1066 uses the parity check data for decoding. The data buffer 1067 temporarily saves the user data received from the host 108 before storing it to the memory device 104, and temporarily saves the data read from the memory device 104 before sending it to the host 108.

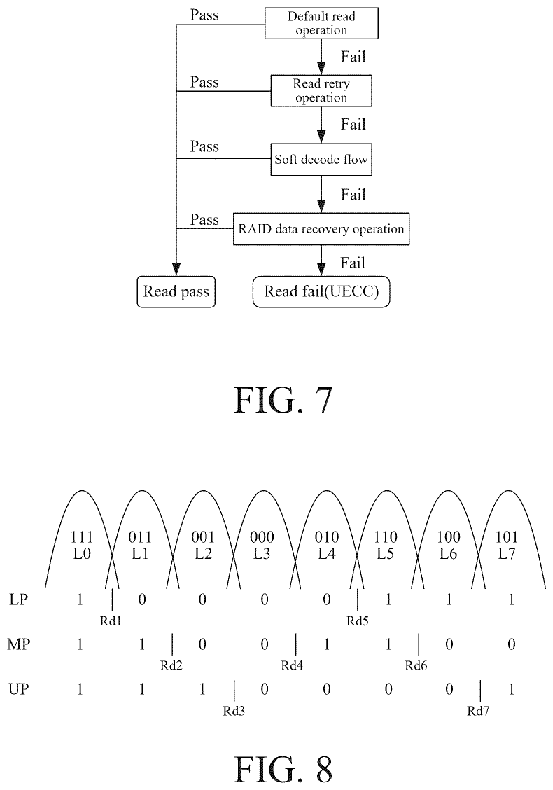

According to some aspects of examples of the present disclosure, FIG. 7 is a schematic diagram illustrating an example operation flow of the memory system 102 for dealing with a read operation fail. Referring to FIG. 7, when the memory controller 106 controls the memory device 104 to perform the read operation, a default read operation is first performed on the memory cell of a respective physical address. After the default read operation fails, an access to a read retry table (RRT) is performed to acquire a voltage offset value, and the voltage offset value and a default read voltage are summed up to obtain a read retry voltage for a read retry operation. The default read voltage is a value calibrated in factory tests of the memory device, and is stored in the memory device for calling by the memory controller or the peripheral circuit of the memory device. The read retry operation and the default read operation may employ hard bit decode (HB decode). After a read retry operation fails, a soft decode flow, which is also referred to as a soft decision, is performed. The soft decode flow may comprise a hard bit read (HB read), wherein hard read data employs the hard bit decode or updates a log likelihood rate (LLR) table independent of an LDPC algorithm. The soft decode flow may also comprise a soft bit read (SB read), wherein the soft read data employs the soft bit decode. After the soft decode flow fails, a Redundant Array of Independent Disks (RAID) or Redundant Array of Independent NANDs (RAIN)-based data recovery operation is performed. After the RAID or RAIN-based operation fails, the ECC error correction operation stops, a read fail occurs due to inability of the error correction, and the memory controller 106 sends a read fail or UECC signal to the host 108.

In an example, RAID may be a disk-level data recovery technology, wherein one memory device 104 may act as one disk, a plurality of disks constitute a disk array, and when an error occurs in a read of data in one or more disks, error data may be recovered through check data and data in a disk subjected to no errors. The check data may be generated during a disk write stage according to written data. The RAIN may be referred to as NAND-level RAID. For the memory device 104 comprising a NAND memory array, the check data may be generated during a program stage based on program data of a plurality of data blocks, and stored in an over-provisioning (OP) region of the memory device 104, wherein one data block may comprise data of one memory cell or of a plurality of memory cells on one word line. When an error occurs in a read of data in one or more data blocks, error data may be recovered according to the check data and non-error data.

The error correction module 1064 (e.g., an ECC module) in the memory controller 106 may control the memory device 104 to perform error correction operations such as a read retry operation, an operation of finding an optimal read voltage, a soft decode operation, and a RAID-based operation. The control command is sent by the memory controller 106 to the memory device 104 via the interface 516. The memory device 104 feeds back read information to the memory controller 106 via the interface 516. It is to be noted that the performance of subsequent operations may be stopped after any one of the read retry operation, the soft decode flow, and the RAID-based operation succeeds.

In some examples, the soft decode operation may be understood as performing data re-decoding through the decoding portion 1066 (e.g., a soft decoder) in the memory controller 106 and performing the read operation again according to re-decoded data. The RAID or RAID-based operation etc. may be understood as implementing data mirroring through secondary coding, to rebuild memory data and parity check data thereof, wherein recoding of a redundant array for the memory data is typically performed in the data buffer 1067 of the memory controller 106.

In some examples, FIG. 8 is a schematic diagram illustrating a threshold voltage distribution of 8 data states of a TLC memory cell, wherein the horizontal axis represents a voltage, and the vertical axis represents a number of memory cells. Referring to FIG. 8, a coding rule of a Gray code may be applied during the programing of a memory cell. A three-bit Gray code applied in a three-bit memory cell TLC is used as an example. Codes 111, 011, 001, 000, 010, 110, 100, and 101 respectively correspond to an erase state (L0) and seven memory states (L1-L7). As described above, seven read voltages (or seven orders of read voltages) Rd1-Rd7 are required to read a distribution of eight threshold voltages corresponding to eight data states (one erase state and seven memory states). A threshold voltage being less than Rd1 corresponds to an L0 data state, a threshold voltage between Rd1 and Rd2 corresponds to an L1 data state, and a threshold voltage being greater than Rd7 corresponds to an L7 data state. For the memory cell with a larger memory bit count, e.g., the QLC memory cell which has 16 data states, the 16 data states are distinguished from each other using read voltages Rd1-Rd15. It is to be noted that, based on the read logic of the multi-bit memory cell, all the data states are distinguished from each other after the read with the plurality of read voltages. The read voltage may be between the threshold voltage distributions of two data states, e.g., at the valley. One read voltage may correspond to any one or both of the adjacent data states distinguished with the read voltage, for example, the read voltage Rd7 may correspond to the data state L7, or may correspond to the data state L6, or is a read voltage between the data state L7 and the data state L6. In this example of the present disclosure, for case of explanation and illustration, Rd7 corresponds to the data state L7, and Rd1 corresponds to the data state L1, which are no longer repeated below.

In some examples, a coding rule of a three-bit Gray code may be used to make three pages corresponding to a three-level memory cell respectively correspond to seven read voltages, wherein a lower page (LP) corresponds to the first read voltage Rd1 and the fifth read voltage Rd5. A middle page (MP) corresponds to the second read voltage Rd2, the fourth read voltage Rd4, and the sixth read voltage Rd6. An upper page (LP) corresponds to the third read voltage Rd3 and the seventh read voltage Rd7. It is to be noted that, after the coding rule is changed, a corresponding number of read voltages is also correspondingly adjusted. The read voltages may be applied according to the pages during the read operation. For example, Rd1 and Rd5 corresponding to the LP may be applied to read the LP, wherein a threshold voltage being less than Rd1 is read as 1, a threshold voltage between Rd1 and Rd5 is read as 0, and a threshold voltage being greater than Rd5 is read as 0. Rd2, Rd4, and Rd6 corresponding to the MP page may be applied, wherein a threshold voltage being less than Rd2 is read as 1, a threshold voltage between Rd2 and Rd4 is read as 0, a threshold voltage between Rd4 and Rd6 is read as 1, and a threshold voltage being greater than Rd6 is read as 0. After the applying of the read voltages corresponding to the LP, MP, and UP similarly, a bit value for each data state, e.g. 111 for L0, is read by aggregating the read data for decoding.

In some examples, in FIG. 7, the default read operation with the default read voltage may not correctly read data, and a read retry operation may be performed to perform error correction. A process of determining a read retry voltage during the read retry operation may comprise: the error correction module 1064 in the memory controller 106 acquires a corresponding voltage offset value by querying a respective read retry table, wherein the voltage offset value may be either a positive offset value or a negative offset value, and the voltage offset value and the default read voltage are summed to obtain the read retry voltage. The memory controller 106 controls the memory device 104 to perform the read retry operation for the memory cell of the respective physical address with the read retry voltage. The default read voltage may be a read voltage default value obtained by the memory device 104 or the memory system 102 according to a threshold voltage distribution after a program operation in a factory test stage. Default read voltages may be located at valley voltages of the threshold voltage distribution during the test. For example, the default read voltage Rd1 is located at a valley between a threshold voltage distribution corresponding to a state L0 and a threshold voltage distribution corresponding to a state L1 or near the valley. The default read voltages are stored in a memory region of the memory device 104 for calling by the memory controller 106 or the peripheral circuit of the memory device 104. A read error of a default read voltage may occur when data states cannot be correctly distinguished, because the default read voltage is not at a valley due to an offset of the threshold voltage distribution. The offset of the threshold voltage distribution may be caused by a temperature variation or read disturb.

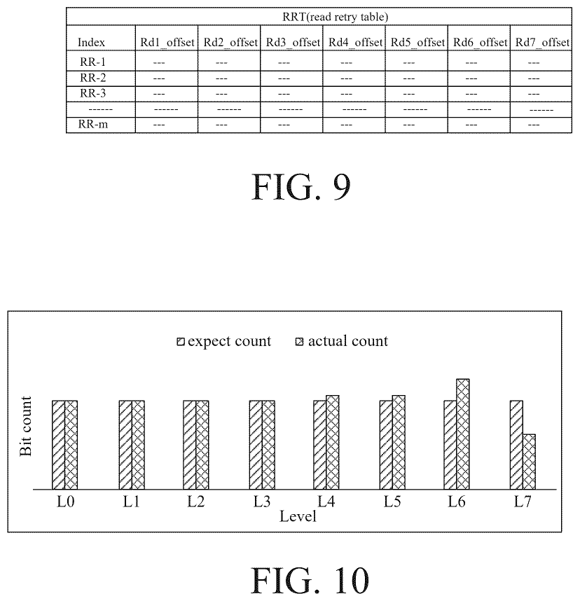

FIG. 9 illustrates an example form of the read retry table for the illustrative purpose only, and the examples of the present disclosure do not limit the form of the read retry table. The read retry table may store or record a plurality of read voltages for distinguishing a plurality of data states of the memory cell, e.g., storing voltage offset values corresponding to read voltages Rd1-Rd7 in FIG. 9, wherein an RR-m entry stores each read voltage offset value, Rd1-Rd7 are used for reading data of the TLC memory cell, and the seven read voltages are used for distinguishing 8 data states comprising the erase state. It is to be noted that the memory controller 106 may query the read retry table in a polling pattern, wherein one read retry table may comprise a plurality of sub-tables, such as m sub-tables, or setting entries of a plurality of rows RR-1 to RR-m in FIG. 9, with m being a natural number greater than 1. Each sub-table may comprise a voltage offset value of a corresponding data state of a corresponding memory cell, and queries are performed sequentially from the first sub-table to the m-th sub-table, one voltage offset value is acquired by one query, and then the voltage offset value and the default read voltage are summed to obtain one read retry voltage, which is used by the memory device 104 to perform a read operation. One read retry operation may comprise at most m read sub-operations, and the examples of the present disclosure are not limited thereto. For example, V1 illustrated in the read retry table is a voltage offset value of the read voltage Rd1, and during polling of the read retry table, the queries may be performed successively starting from RR-1 of the first index to RR-m, to obtain the read retry voltages sequentially to perform the read retry operations until the read succeeds. Alternatively, an index of a read retry table may be located according to a preset condition, and a segment of an index item of the read retry table is acquired without loading all the index items.

In some examples, the read retry table may correspond to the default read voltages for respective data states, and the read retry voltage is obtained by summing the default read voltage and the voltage offset value recorded in the read retry table. The default read voltage is a calibrated value determined in factory tests of the memory device 104. A reference value for summing each default read voltage and the voltage offset value in the read retry table may vary, i.e., the default read voltage corresponding to each data state may vary. In some other examples, after a read fail of the memory cell, taking the current read voltage of the read fail as a reference, the voltage offset value is obtained by querying the read retry table, and the read retry voltage is obtained by summing the voltage offset value and the current read voltage, wherein the current read voltage of the read fail may be any value and may not be equal to the default read voltage. For example, a voltage for performing the default read operation may be the above-mentioned default read voltage, or may be a voltage obtained by offsetting the default read voltage, or may be another voltage, e.g., a read try voltage. A voltage value is not limited. For example, a read voltage corresponding to one selected data state (a first data state) in a plurality of data states may be used to perform the default read operation. The first read state may be a state L7, the first read voltage may be Rd7, and Rd7 may be a default read voltage value or may be another voltage value.

In some examples, during programming of the memory cell, writing may be performed in a data randomization mode. During programming of the memory cells of a minimum program unit (or a minimum program region) in the memory device 104, the memory cells of the minimum program unit are all memory cells on one word line or memory cells on a partial region of one word line in which reads and writes can be performed independently. Numbers of memory cells corresponding to any two data states are equal or approximately equal within a certain error range, the memory cell of which a target data state is the erase state will not be programmed. For a TLC memory cell, a threshold voltage distribution after program may be shown in FIG. 8. A threshold voltage distribution of each data state is a normal distribution or is a normal distribution within a certain error range, and areas of threshold voltage distribution peaks of any two data states are equal or approximately equal within a certain error range. In FIG. 8, a total number of the memory cells in the minimum program unit may be Z. The TLC has a total of 8 data states, and the number of memory cells corresponding to each data state may be configured as Z/8. In the subsequent read process, it is expected that the number of memory cells corresponding to each data state is expected to be read as Z/8. However, due to a threshold voltage offset, if the read is performed still with the read voltage determined from a random threshold voltage distribution, the number of memory cells corresponding to some data states may differ from Z/8 greatly, causing the read of some memory cells programmed to the state Li to be read as the state Lj in the read process, or the read of some memory cells programmed to the state Lj to be read as the state Li. The state Li and the state Lj are adjacent data states.

In some examples, FIG. 10 is a schematic diagram illustrating numbers corresponding to data states in a TLC memory cell, wherein the horizontal axis represents a data state, and the vertical axis represents the number of memory cells (bit count). Based on a program logic of the random distribution, when the threshold voltage of the memory cell is subjected to no offset or the threshold voltage offset is not considered, the read bit count of each data state may be recorded as an expect count, which may be an expect count set to be achieved during the program operation, and an actually read bit count of each data state is an actual count. The threshold voltage offset cause an actual count of a certain data state to be greater than or less than an expect count, and a difference between the two numbers is large and exceeds a predetermined deviation range, thereby causing a read error. For example, an actual count corresponding to the data state L7 is less than an expect count, with a difference exceeding the predetermined deviation range. An actual count corresponds to the data state L6 is greater than an expect count, with a difference exceeding the predetermined deviation range. In some other examples, the expect count may be a determined value calibrated in a factory test stage of the memory device 104 or the memory system 102, the setting value may be determined based on a Gray code coding rule of the memory cell, and the expect count may be stored in a memory region of the memory device 104 as the setting value for calling by the memory controller 106.

In some examples, a mapping table may be established according to differences between expect counts and actual counts of data states and read voltage offset values corresponding to the differences, to replace the read retry table shown in FIG. 9. The mapping table stores a plurality of intervals of value, each interval of value corresponds to a voltage offset value, and an access rate of the mapping table is greater than an access rate of the read retry table, thereby increasing an operation rate. In some examples, reference may be made to actual counts and expect counts corresponding to data states calculated when read errors occur by applying a plurality of read voltages, shown in FIG. 10. For example, the number of memory cells corresponding to the state L7 is Z1, an expect count is Z/8, and a related mapping table is accessed according to a difference between Z1 and Z/8. When the difference is in a interval of value, a voltage offset value corresponding to the interval of value is acquired, and the voltage offset value and a corresponding read voltage are summed to obtain a new read voltage to perform a read retry for error correction on the memory cells. The expect count, the interval of value, and corresponding voltage offset values are values calibrated in the factory test stage and stored in a memory region of the memory device 104 for calling by the memory controller 106.

In some examples, the read retry operation may not require the applying of all the read voltages prior to calculating actual counts. The memory controller 106 may control the memory device 104 to enable a Single level read (SLR) mode. The memory device 104, in response to the operation instruction, performs a single level read operation on a memory cell at a corresponding address with a read voltage. The single level read operation may comprise reading at least one bit of memory data stored in the memory cell through one read voltage, or in other words, in this case, the memory cell is configured as an SLC and read with one read voltage, and statistics of bit information read from the memory cell is collected. A memory cell with a threshold voltage being less than or equal to than the read voltage is read as 1, and a memory cell with a threshold voltage being greater than the read voltage is read as 0, without applying a plurality of levels of read voltages prior to collecting statistics of the bit information. Examples of the present disclosure provide the memory controller 106 and the memory system 10. For an error correction process of a read retry operation, a single level read operation is performed on one read voltage. A number of memory cells read as 1s is calculated, and a number of memory cells read as 0s is calculated. A mapping relationship between a difference between the two numbers and a voltage offset value is established, and a corresponding mapping table is formed. The mapping table is queried according to an actual read difference to determine a read voltage offset value to acquire a read retry voltage, thereby improving an operation rate.

According to some aspects of examples of the present disclosure, the memory controller 106 is provided in FIG. 1. The memory controller 106 is configured to: control the memory device 104 to perform a read operation with a first read voltage corresponding to a first data state of a memory cell; obtain the first number of memory cells with a threshold voltage being less than or equal to the first read voltage, and obtain the second number of memory cells with a threshold voltage being greater than the first read voltage; determine a difference between the second number and the first number; and acquire a voltage offset value from a mapping table according to the difference.

The first read voltage is a voltage, an error occurs when data is read with the voltage during a default read operation performed in FIG. 7, is a read voltage to be performed error correction, and may be a default read voltage stored in the memory device 104 or another read voltage to be performed error correction. A value of the read voltage is not specifically limited in the present application. A second read voltage is obtained by summing the first read voltage and a voltage offset value acquired from a related mapping table, and the second read voltage is used to perform read retry to perform error correction. If the read retry of the second read voltage passes in this case, it indicates that error correction succeeds, and if the read retry fails, a soft decode operation may be performed to continue with error correction. The first read voltage may be any one of read voltages Rd1-Rd7 shown in FIG. 8. That is, after an error occurs when any one of Rd1-Rd7 is used to perform a default read operation, a read retry operation needs to be performed to perform error correction. This voltage to be performed error correction may be recorded as the first read voltage of the present disclosure, and a data state corresponding to the first read voltage is the first data state or a selected data state. For example, when the first data state is a data state L7, a read voltage Rd7 corresponding to the first data state is a first read voltage Rd7. When the first data state is a data state L6, a read voltage corresponding to the first data state is a first read voltage Rd6.

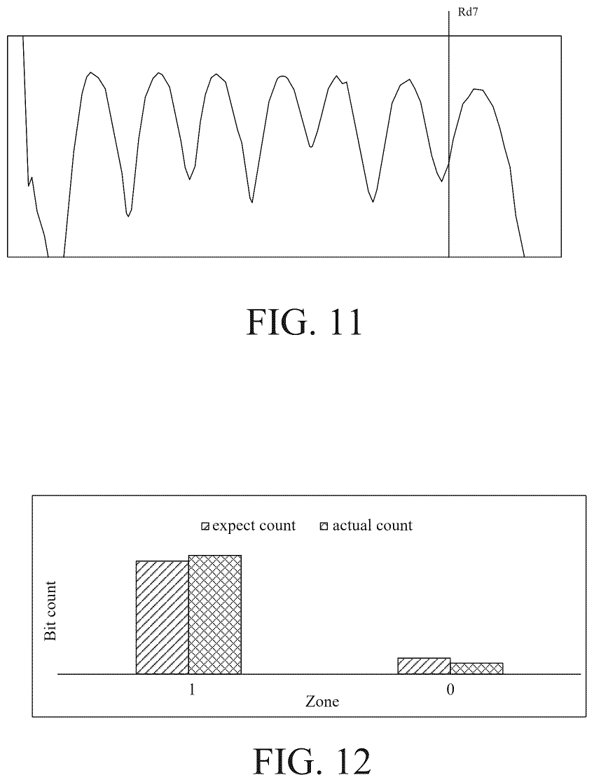

As shown by the example in FIG. 11, a single level read operation is performed on a memory cell at a corresponding address with the first read voltage Rd7 corresponding to the data state L7. The memory cells on the left of RL7 with a threshold voltage being less than or equal to Rd7 are turned on, the read thereof passes, and at this time, the number of the memory cells on which read passes may be calculated as, e.g., the first number. The memory cells on the right of the read voltage RL7 with a threshold voltage being greater than Rd7 are not turned on, the read thereof fails, and at this time, the number of the memory cells that fail to be read may be calculated as, e.g., the second number.

In some examples, the first number and the second number of Rd7 in the TLC memory cell may be referred to FIG. 12. The first number and the second number are both actually read actual counts. Different first numbers and second numbers may be obtained from different read voltages or different threshold voltage offsets. The first number corresponds to a calibrated first expect count, and the second number corresponds to a calibrated second expect count. With reference to a threshold voltage distribution of the TLC memory cell in FIG. 8, threshold voltage distributions corresponding to all data states are used as statistical objects. A number of memory cells with a threshold voltage being less than or equal to Rd7 is the first expect count of Rd7 in FIG. 11, and may be 7Z/8. A number of memory cells with a threshold voltage being greater than Rd7 is the second expect count of Rd7 in FIG. 11, and may be Z/8. A difference between the second expect count Z/8 and the first expect count 7Z/8 is −6Z/8. The expect count is determined by program logic based on the foregoing random distribution, and is obtained by test locating in the factory test stage and stored in a memory region of the memory device 104, or may be any other value calibrated in the factory test. In a further example, the first expect count of the read voltage Rd6 corresponding to the data state L6 is 6Z/8, the second expect count is 2Z/8, and a difference is −4Z/8. After the threshold voltage distribution is offset, Rd7 or Rd6 is used to perform the read operation to acquire the first number and the second number. The first number is not equal to the first expect count, the second number is not equal to the second expect count, and a difference ΔZ between the second number and the first number is also not equal to an expect difference. The difference ΔZ may be used to represent an offset degree of a valley of the threshold voltage relative to the first read voltage, and mapping is performed on the difference ΔZ and a voltage offset value to generate a mapping table. Subsequently, after a different first read voltage is used to perform reading and a difference ΔZ is obtained, a voltage offset value corresponding to the difference may be obtained by looking up the mapping table.

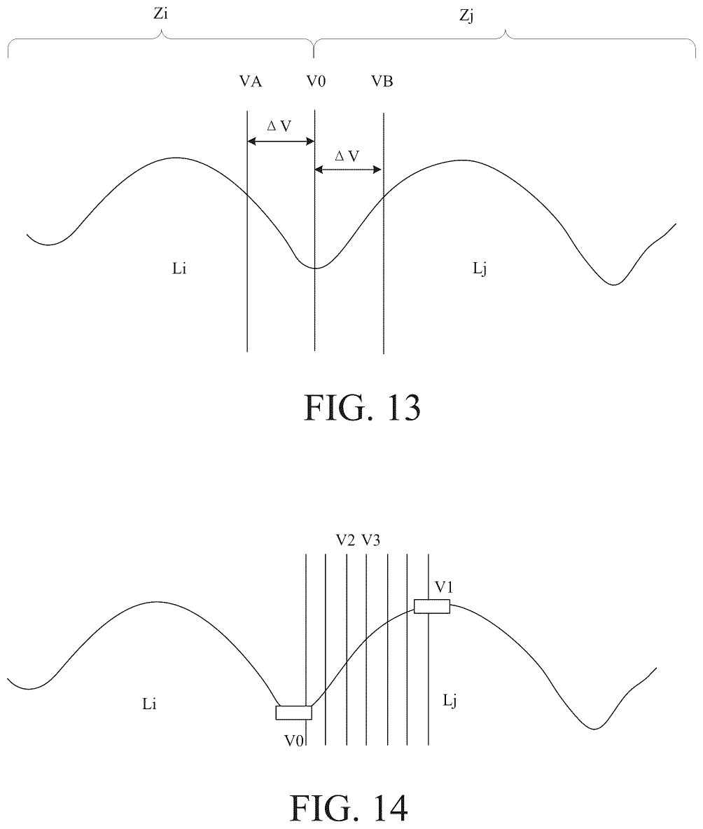

In some examples, referring to FIG. 13, threshold voltage distributions of two adjacent data states Li and Lj are used as an example. V0 is a valley voltage between two threshold voltage distributions. The valley voltage is an optimal read voltage of each threshold voltage distribution. A first read voltage to be performed error correction is located at VA or VB due to an offset of the threshold voltage distribution to cause a read error. It may be understood that when being located at VA, the first read voltage needs to be offset to the right to obtain an optimal read voltage, and when being located at VB, the first read voltage needs to be offset to the left to obtain an optimal read voltage. A difference between VA and V0 may be ΔV, a difference between VB and V0 may be ΔV, and a variation of a number of memory cells caused by the offset ΔV of the voltage relative to V0 is defined as ΔS. For example, ΔS is a number of memory cells of the threshold voltage between VA and V0, or ΔS is a number of memory cells with the threshold voltage being between V0 and VB. A number of memory cells with a threshold voltage being less than or equal to V0 is denoted as Zi, and a number of memory cells with a threshold voltage being greater than V0 is denoted as Zj. When the first read voltage VB is used to perform reading, the first number of memory cells with a threshold voltage being less than or equal to VB is Zi+ΔS, the second number of memory cells with a threshold voltage being greater than VB is Zi−ΔS, and a difference obtained by subtracting the first number from the second number is ΔZ_B=Zj−Zi−2ΔS. When the first read voltage VA is used to perform reading, the first number of memory cells with a threshold voltage being less than or equal to VA is Zi−ΔS, the second number of memory cells with a threshold voltage being greater than VA is Zj+ΔS, and a difference obtained by subtracting the first number from the second number is ΔZ_A=Zj−Zi+2ΔS. Zj and Zi are calibrated values, and ΔS is a statistical value of actual read information. The difference ΔZ and ΔS have a corresponding relationship.

In some examples, for example, a memory cell has 2ⁿ data states, and each data state of the plurality of data states is distinguished with 2ⁿ−1 read voltages. Li is an ith data state of the data states, and Lj is a jth data state of the data states. A first number corresponding to the valley voltage V0 is Zi=Z*j/2ⁿ. A total number of memory cells in a minimum program unit is Z, and is a calibrated expect count. A second number corresponding to V0 is Zj=Z*(1−j/2ⁿ). A difference between the second number and the first number is Zj−Zi=Z*(1−2j/2ⁿ). When the threshold voltage offset is larger, ΔS is larger (ΔS is a positive value). When ΔS changes, the corresponding difference ΔZ between the second number and the first number changes accordingly. Differences between different second numbers and first numbers, and voltage offset values corresponding to the differences may be tested. A valley voltage or a voltage close to a valley voltage may be obtained by summing the first read voltage and the voltage offset value. The voltage offset value may be a positive value or a negative value. A mapping relationship exists between a difference and a voltage offset value. After a difference corresponding to a first read voltage is acquired, a voltage offset value may be obtained according to the mapping relationship, and the first read voltage and the voltage offset value are summed to obtain a second read voltage to perform read error correction.

In some examples, referring to FIG. 14, an intercept between the valley voltage V0 and a peak voltage Lj is divided into a plurality of parts or a plurality of voltage intervals. Interval ranges of any two valley interval may be equal or not equal. A value range of a difference ΔZ between a second number and a first number corresponding to each voltage interval is tested. A minimum value and a maximum value of each voltage interval are at least tested to obtain a interval of value (a interval, a range of value) of the difference ΔZ. The interval of value of the difference ΔZ may be recorded to form a mapping table. When the difference ΔZ is a negative value, an absolute value of the difference may be recorded to form a mapping table. The mapping table further records voltage offset values corresponding to the interval of value. The voltage offset value may be an offset value of any one value in the voltage interval relative to V0. A voltage interval V2-V3 of 6 voltage intervals between V0 and Vj in the figure is used as an example. When a first read voltage Rdj corresponding to a data state Lj is within the voltage interval V2-V3, a difference ΔZ between the second number and the first number corresponding to Rdj=V2 and a difference ΔZ between the second number and the first number corresponding to Rdj=V3 are at least tested. The two differences constitute one interval of value. A voltage offset value corresponding to the interval of value may be any value in intervals (V2−V0)−(V3−V0), comprising, but not limited to, ½(V3−V2). For another voltage interval, a interval of value of a difference may also be tested with reference to the voltage interval V2-V3, and a plurality of intervals of value and voltage offset values corresponding to the intervals of value are recorded and a mapping table is generated. The mapping table may be calibrated and generated in the factory test stage and stored within the memory device 104 for calling by the memory controller 106.

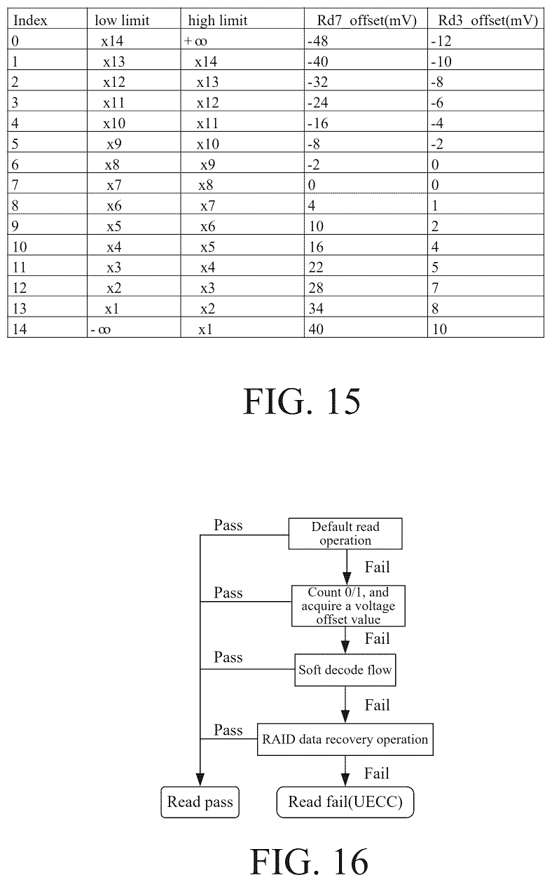

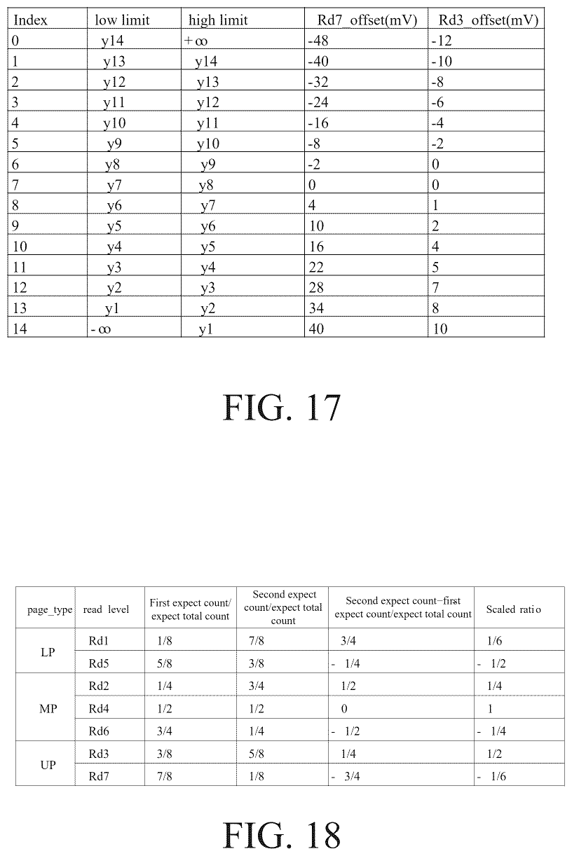

The difference ΔZ between the second number and the first number is multiplied by an association coefficient Sr (Scaled ratio) to perform mathematical normalization, to make values of the intervals of value converge in small intervals of value. A interval of value obtained after the association coefficient is multiplied is a first interval of values, the original interval of value before the association coefficient is multiplied is a second interval of values, and corresponding voltage offset values belonging to the first interval of values and the second interval of values are the same. The association coefficient may also be referred to as a normalization coefficient or a convergence coefficient, and is calibrated in the factory test stage and stored in the memory device for calling by the memory controller 106. A second mapping table may be shown in FIG. 15, and a first mapping table may be shown in FIG. 17 below. Indexes in the second mapping table in FIG. 17 corresponds to those in the first mapping table in FIG. 15. For example, voltage offset values corresponding to Index0 and Index1 in FIG. 17 may be respectively equal to offset values of Index0 and Index1 in FIG. 15. The first interval of values may be denoted by y, and the second interval of values may be denoted by x, wherein y14=x14*Sr, y13=x13*Sr, and y1=x1*Sr.

The mapping tables in the examples in FIG. 15 and FIG. 17 in some examples may adapt to a TLC memory cell, and store a voltage offset value Rd7_offset of Rd7 and a voltage offset value Rd3_offset of Rd3 corresponding to an Up page. In some other examples, the mapping table may only store voltage offset values for one read voltage, or voltage offset values for all read voltages.

In some examples, referring to FIG. 15, the mapping table may comprise a second mapping table which comprises a second interval of values and voltage offset values corresponding to the second interval of values; and the memory controller 106 is configured to: in response to the difference being within the second interval of values, acquire the voltage offset value corresponding to the second interval of values according to the second mapping table. In some examples, the memory controller 106 is further configured to sum the first read voltage and the voltage offset value to obtain a second read voltage.

With reference to FIG. 16, the read retry operation in FIG. 13 is improved in examples of the present disclosure. After a default read operation performed with the first read voltage fails, the memory controller 106 sends an operation command and address information to the memory device 104. The memory device 104 enables a single level read operation in response to the operation command, and performs a single level read operation on a memory cell at a corresponding address with the first read voltage. A peripheral circuit of the memory device 104 reads a memory cell with a threshold voltage being less than or equal to the first read voltage as 1, reads a memory cell with a threshold voltage being greater than the first read voltage as 0, calculates a number of Is as a first number, calculates a number of 0s as a second number, and sends the first number and the second number to the memory controller 106, or the memory controller 106 calculates a first number and a second number according to a read result of Is and 0s. The memory controller 106 performs subtraction on the second number and the first number to obtain a difference ΔZ, and an absolute value of ΔZ may be taken when ΔZ is negative. The memory controller 106 accesses a data buffer or a RAM inside the memory controller, or accesses the second mapping table in the example shown in FIG. 15 stored in a DRAM of the memory system 102. The second mapping table stores a voltage offset value corresponding to the first read voltage, or a voltage offset value corresponding to a data state to which the first read voltage belongs. A second interval of values to which the difference ΔZ belongs is determined, a voltage offset value corresponding to the second interval of values to which the difference ΔZ belongs is acquired, and the first read voltage and the voltage offset value are summed to obtain a second read voltage to perform read retry to perform error correction. In some examples, when the memory system 102 is shut down, the second mapping table may be stored in the memory device 104.

In an example, after a first read voltage Rd7 is used to perform reading and a difference ΔZ is acquired, the second mapping table in the example shown in FIG. 15 is accessed. When ΔZ is greater than or equal to x14, a voltage offset value Rd7_offset is acquired as −48 eV. When ΔZ is less than or equal to x1, Rd7_offset is acquired as 40 eV. When ΔZE [x13, x14], Rd7_offset is acquired as −40 eV. When ΔZ is at an endpoint of the second interval of values, a voltage offset value corresponding to ΔZ may be randomly taken, and a value is no longer taken after reading succeeds. When an index to which ΔZ belongs is loaded to perform read retry and the read retry still fails, another index may be loaded to perform read retry until the read retry succeeds. If the read retry still fails after all indexes have been loaded, it indicates that error correction cannot be performed by loading voltage offset values through the second mapping table for the current first read voltage, and a soft decode operation may be enabled. When a first read voltage Rd3 is employed to perform reading and a difference ΔZ is acquired, the second mapping table shown in FIG. 15 may also be accessed to acquire Rd3_offset values to perform read retry to perform error correction. When other read voltages such as Rd1, Rd2, Rd4, etc. are employed, another second mapping table recording corresponding read voltage offset values may be accessed.

In some examples, referring to FIG. 17, the mapping table comprises a first mapping table which stores a first interval of values and voltage offset values corresponding to the first interval of values; and the memory controller 106 is configured to: multiply the difference by an association coefficient to obtain a feature value; and in response to the feature value being within the first interval of values, acquire the voltage offset value corresponding to the first interval of values according to the first mapping table. After the first read voltage is used to perform reading and a difference ΔZ between a second number and a first number is acquired, ΔZ is multiplied by an association coefficient Sr to obtain a feature value ΔZ*Sr. The first mapping table in the example of FIG. 17 is accessed. The first mapping table stores a voltage offset value corresponding to the first read voltage. The first interval of values corresponding to the voltage offset value is a product of multiplying the second interval of values of the second mapping table of FIG. 15 by the association coefficient. The second interval of values of the second mapping table of FIG. 15 may be seen as a product of multiplying the second interval of values by the association coefficient being 1. A first interval of values to which the feature value ΔZ*Sr belongs is determined, a voltage offset value corresponding to the first interval of values to which the feature value ΔZ*Sr belongs is acquired, and the first read voltage and the voltage offset value are summed to obtain a second read voltage to perform read retry to perform error correction.

In an example, after the first read voltage Rd7 is used to perform reading and the difference ΔZ is acquired, the feature value ΔZ*Sr is calculated, and the first mapping table in the example shown in FIG. 16 is accessed. When ΔZ*Sr is greater than or equal to y14, a voltage offset value Rd7_offset is acquired as −48 eV. When ΔZ*Sr is less than or equal to y1, Rd7_offset is acquired as 40 eV. When ΔZ*Sr∈[y13, y14], Rd7_offset is acquired as −40 eV. When ΔZ*Sr is at an endpoint of the first interval of values, a voltage offset value corresponding to ΔZ may be randomly taken, and a value is no longer taken after reading succeeds. When an index to which ΔZ*Sr belongs is loaded to perform read retry and the read retry still fails, another index may be loaded to perform read retry until the read retry succeeds. If the read retry still fails after all indexes have been loaded, it indicates that error correction cannot be performed through the first mapping table for the current first read voltage, and a soft decode operation may be enabled. When a first read voltage Rd3 is employed to perform reading and the feature value ΔZ*Sr is obtained, the first mapping table shown in FIG. 16 may also be accessed to acquire Rd3_offset values to perform read retry to perform error correction. When other read voltages such as Rd1, Rd2, Rd4, etc. are employed, another first mapping table recording corresponding read voltage offset values may be accessed. Specific values of the interval of value are not limited in examples of the present disclosure. The interval of value may be calibrated in the factory test stage. For example, y1 may be 14536, y12 may be 20902, and y13 may be 22199. Ranges in interval of values may be equal or not equal. The definition and locating of the association coefficient are described with reference to FIG. 18 below.

In some examples, each memory cell in the memory device 104 is configured to store one of a plurality of data states; and the association coefficient corresponds to a data state, and association coefficients corresponding to different data states are not equal. In some examples, the plurality of data states comprise 2ⁿ data states, and each data state of the plurality of data states is distinguished with 2ⁿ−1 read voltages; and a sum of a feature value corresponding to the ith read voltage and a feature value corresponding to the (2ⁿ−i)th read voltage is zero, wherein n is an integer greater than 1, i is a positive integer less than 2ⁿ−1, and i is not equal to 2ⁿ−i.

In some examples, referring to FIG. 18, read levels may be read voltages Rd1-Rd7 shown in FIG. 8, and respectively correspond to data states L1-L7. Rd1 is used as an example. In an optimal state that a threshold voltage distribution has no offset, a memory cell with a threshold voltage being less than or equal to Rd1 is read as “1”, of which a number is a first expect count, and a memory cell with a threshold voltage being greater than Rd1 is read as “0”, a number of which is a second expect count. An expect total number is Z, and Z may be a total number of memory cells in a minimum program unit. For the ith read voltage, the first expect count is Z*i/2ⁿ, the second expect count is Z*(1−i/2ⁿ), a difference between the second expect count and the first expect count is Z*(1−2i/2ⁿ), and i may be a positive integer less than or equal to 2ⁿ. A value of the first expect count/the expect total number is i/2ⁿ, a value of the second expect count/the expect total number is 1−i/2ⁿ, and a value of (the second expect count—the first expect count)/the expect total number is 1−2i/2ⁿ. The association coefficient Sr is set in the examples of the present disclosure, such that Sr*(1−2i/2ⁿ)=1/2ⁿ, then Sr=(1/2ⁿ)/(1−2i/2ⁿ)=1/(2ⁿ−2i). When i=2ⁿ−i, Sr=1/(2i−2ⁿ). However, when i is 2ⁿ/2, Sr is 1. In this case, the difference between the second expect count and the first expect count is 0. Values near Z/8 are taken in the construction of the first interval of values of the first mapping table in FIG. 17, and are all positive values, thereby reducing the difficulty of locating and testing of the first mapping table. Data in FIG. 18 corresponds to a TLC memory cell. Taking Rd1 as an example, i=1, and 2ⁿ=8. It can be calculated that the first expect count/the expect total number is 1/8, the second expect count/the expect total number is 7/8, a ratio of a difference to the expect total number is 3/4, and Sr is 1/6. Data calculated through Rd7 is sequentially 7/8, 1/8, −3/4, and −1/6. A Sr value of Rd1 and an Sr value of Rd7 are opposite numbers of each other and have the same absolute value. For different read voltages, Sr values of the different read voltages are different.

For the second mapping table shown in FIG. 15, during locating of the second interval of values of the second mapping table, a plurality of read voltages and corresponding voltage offset values may be tested. A difference ΔZ between the second number and the first number is recorded, and when the difference ΔZ is a negative value, an absolute value of the difference may be taken. The second interval of values and the corresponding voltage offset values may be calibrated according to the difference ΔZ (or the absolute value thereof) to generate the second mapping table to be stored in the memory device 104 for calling by the memory controller 106. For the first mapping table shown in FIG. 17, during locating of the first interval of values of the first mapping table, the difference ΔZ needs to be multiplied by the association coefficient Sr (Sr may be positive or negative). The first interval of values and the corresponding voltage offset values are calibrated according to ΔZ*Sr, and the first mapping table is generated and stored in the memory device 104 for calling by the memory controller 106. The mapping table may be first loaded to the data buffer or RAM or in the DRAM of the memory system 102 for calling by the memory controller 106. During error correction, the first read voltage is used for reading, and the difference ΔZ is acquired. If the first mapping table is called, the difference ΔZ is multiplied by the association coefficient Sr to obtain the feature value ΔZ*Sr, the first interval of values of the first mapping table is determined according to ΔZ*Sr, and a corresponding index is loaded to acquire the voltage offset value to perform read retry to perform error correction. It may be understood that the difference ΔZ cans be multiplied by the association coefficient being 1 to correspond to the second mapping table shown in FIG. 15.

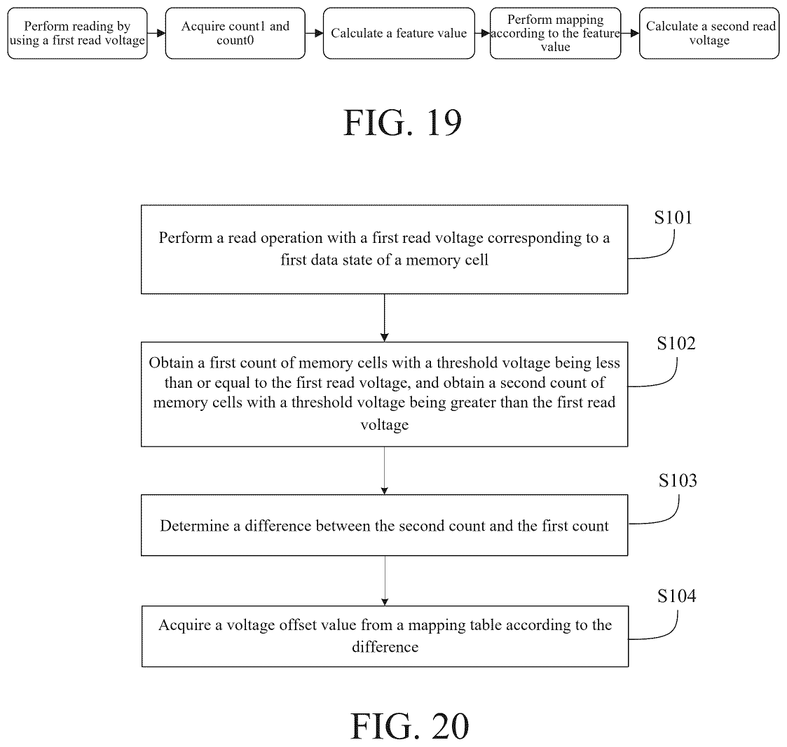

In some examples, FIG. 19 shows an example of an error correction operation of a first read voltage provided by examples of the present disclosure. The memory controller 106 controls the memory device 104 to perform single-state reading on a memory cell at a related address with the first read voltage. The memory controller 106 acquires a first number (count 1) and a second number (count 0), calculates a feature value ΔZ*Sr, and queries the first mapping table according to the feature value to acquire a voltage offset value, sums the first read voltage and the voltage offset value to obtain a second read voltage, performs read retry with the second read voltage, and determines whether error correction succeeds.

Compared with a conventional read retry table, the first mapping table or second mapping table in examples of the present disclosure has a small data amount, such that a data occupation space of the mapping table can be reduced; and during read retry error correction of the first read voltage, a corresponding mapping table may be accessed according to the difference ΔZ or the feature value ΔZ*Sr and a interval of value may be located, and voltage offset values for a corresponding interval of value are loaded. It is not necessary to load all mapping tables. Thus, an error correction rate is increased, thereby improving user experience.

In some examples, the first mapping table stores a first interval of values for the first data state and stores voltage offset values corresponding to the first interval of values; and the voltage offset values are stored in the first mapping table in order of magnitude. The values may be arranged in order of magnitude in the first interval of values, and corresponding read voltages are arranged in order of magnitude, to facilitate query and locating of the first interval of values. One first mapping table may be configured for one read voltage. For example, only a voltage offset value Rd7_offset corresponding to Rd7 and a corresponding first interval of values are recorded in one first mapping table. For error correction of read voltages Rd1-Rd7, 7 first mapping tables may be set for adaption. One second mapping table may be configured for one read voltage.

In some examples, the 2ⁿ−1 read voltages are divided into a plurality of groups; one first mapping table stores a first interval of values corresponding to one group of read voltages, and one first interval of values corresponds to voltage offset values for the group; voltage offset values for the read voltage for the highest data state in the group are stored in order of magnitude; and the memory controller 106 is further configured to: perform a read operation with a first read voltage corresponding to the highest data state in the group; and in response to the feature value being within the first interval of values, acquire a voltage offset value for the group corresponding to the first interval of values.

A group of read voltages may be a page shown in FIG. 8. For example, 7 read voltages Rd1-Rd7 of a TLC may be divided into three pages (three groups). An LP page corresponds to Rd1 and Rd5, and may correspond to a data state L1 and a data state L5. An MP page corresponds to Rd2, Rd4, and Rd6. An UP page corresponds to Rd3 and Rd7. Offset trends or degrees of threshold voltage distributions corresponding to data states belonging to a same page are similar, and may be employed in a same interval of value. For example, an offset direction of a threshold voltage distribution corresponding to the data state L3 may be the same as an offset direction of a threshold voltage distribution corresponding to the data state L7. A contraction or expansion degree of a peak of the threshold voltage distribution corresponding to the data state L3 may be the same or close to that of a peak of the threshold voltage distribution corresponding to the data state L7. As such, the same interval of value may be used to simplify the mapping table. In the first mapping table shown in FIG. 17, Rd7_offset and Rd3_offset may be recorded for read voltages Rd7 and Rd3 corresponding to the UP page. One same first interval of values or one same index corresponds to one Rd7_offset and Rd3_offset. For error correction of Rd7 and Rd3, the first mapping table may be respectively queried to acquire a voltage offset value of a required first interval of values. Alternatively, only Rd7 corresponding to the highest state L7 of the UP page is used to perform reading, determine a difference ΔZ, determine a required first interval of values, acquire corresponding Rd7_offset, and automatically acquire other voltage offset values of a same index, that is, acquire all voltage offset values corresponding to a required index, and it is not necessary to determine a difference ΔZ and perform table lookup for another data state lower than the highest state in the same page. For example, the difference determined through Rd7 and the feature value ΔZ*Sr∈[y13, y14] are used to acquire that Rd7_offset is-40 mV and Rd3_offset is-10 mV. For another example, Rd2_offset, Rd4_offset, and Rd6_offset corresponding to the MP page are recorded. Rd6 may be used to perform reading, determine a difference ΔZ, determine a required first interval of values, and acquire Rd2_offset, Rd4_offset, and Rd6_offset corresponding to the first interval of values. In some examples, for the second mapping table shown in FIG. 15, a difference ΔZ determined through Rd7 and ΔZ= [x13, x14] are used to acquire that Rd7_offset is −40 mV and Rd3_offset is-10 mV.

In some examples, a linear relationship exits between at least part of voltage offset values corresponding to the read voltage for the highest data state in the group and at least part of voltage offset values corresponding to read voltages for other data states in the group, to facilitate locating and search of a mapping table. Referring to the first mapping table shown in FIG. 17 and the second mapping table shown in FIG. 15, for Index1-Index5, every time Rd7_offset is increased by 8 eV, Rd3_offset is increased by 2 eV. Such a pattern may not exist in the first interval of values. With reference to the pattern, one Rd7_offset and one Rd3_offset may be recorded, and the remaining voltage offset values may be calculated according to this pattern.

In some examples, the memory controller 106 is configured to: enable a single level read (SLR) operation mode, and control the memory device 104 to perform a single level read operation with the first read voltage. The memory controller 106 sends an operation instruction of enabling a single level read operation mode to the memory device 104. The memory device 104 receives the instruction, enables the single level read mode, receives address information to be operated and first read voltage information, performs a single level read operation on a memory cell at a related address with the first read voltage, reads a memory cell with a threshold voltage being less than or equal to the first read voltage as 1, reads a memory cell with a threshold voltage being greater than the first read voltage as 0, calculates a number of Is as a first number, and calculates a number of 0s as a second number.

According to some aspects of examples of the present disclosure, FIG. 1 and FIG. 6 provide a memory system 102, which comprises: a memory device 104; and a memory controller 106 coupled with the memory device 104, wherein the memory device 104 comprises a plurality of memory cells, and the plurality of memory cells are configured to store one of a plurality of data states; and the memory controller 106 is configured to: control the memory device 104 to perform a read operation with a first read voltage corresponding to a first data state of the plurality of data states; obtain the first number of memory cells with a threshold voltage being less than or equal to the first read voltage, and obtain the second number of memory cells with a threshold voltage being greater than the first read voltage; determine a difference between the second number and the first number; and acquire a voltage offset value from a mapping table according to the difference. The memory controller 106 sends the operation instruction, the address information, and the first read voltage value to the memory device 104. The memory device 104 receives the operation instruction, enables the single-state read operation mode, performs a single level read operation on a memory cell at corresponding address information with the first read voltage, reads a memory cell with a threshold voltage being less than or equal to the first read voltage as 1, reads a memory cell with a threshold voltage being greater than the first read voltage as 0, calculates a number of Is as a first number, and calculates a number of 0s as a second number. The memory device 104 or the memory controller 106 calculates a difference ΔZ between the second number and the first number. The memory controller 106 queries the second mapping table according to the difference ΔZ to acquire a voltage offset value, and sums the voltage offset value and the first read voltage to obtain a second read voltage to perform read retry to perform error correction. Alternatively, the memory controller 106 queries the first mapping table according to the feature value ΔZ*Sr to acquire a voltage offset value to perform read retry to perform error correction.

In some examples, the mapping table comprises a first mapping table which stores a first interval of values and voltage offset values corresponding to the first interval of values; and the memory controller 106 is configured to: multiply the difference by an association coefficient Sr to obtain a feature value; and in response to the feature value being within the first interval of values, acquire the voltage offset value corresponding to the first interval of values according to the first mapping table.

In some examples, the association coefficient corresponds to a data state, and association coefficients corresponding to different data states are not equal.

In some examples, the plurality of data states comprise 2ⁿ data states, and each data state of the plurality of data states is distinguished with 2ⁿ−1 read voltages; and a sum of a feature value corresponding to the ith read voltage and a feature value corresponding to the (2ⁿ−i)th read voltage is zero, wherein n is an integer greater than 1, i is a positive integer less than 2ⁿ−1, and i is not equal to 2ⁿ−i.

In some examples, the first mapping table stores a first interval of values for the first data state and stores voltage offset values corresponding to the first interval of values; and the voltage offset values are stored in the first mapping table in order of magnitude.

In some examples, the 2ⁿ−1 read voltages are divided into a plurality of groups; one first mapping table stores a first interval of values corresponding to one group of read voltages, and one first interval of values corresponds to voltage offset values for the group; voltage offset values for the read voltage for the highest data state in the group are stored in order of magnitude; and the memory controller 106 is further configured to: perform a read operation with a first read voltage corresponding to the highest data state in the group; and in response to the feature value being within the first interval of values, acquire a voltage offset value for the group corresponding to the first interval of values.

In some examples, a linear relationship exits between at least part of voltage offset values corresponding to the read voltage for the highest data state in the group and at least part of voltage offset values corresponding to read voltages for other data states in the group.

In some examples, the mapping table comprises a second mapping table which comprises a second interval of values and voltage offset values corresponding to the second interval of values; and the memory controller 106 is configured to: in response to the difference being within the second interval of values, acquire the voltage offset value corresponding to the second interval of values according to the second mapping table.

In some examples, the memory controller 106 is further configured to: send a first operation command to the memory device 104; and the memory device 104 is configured to: enable a single level read operation mode in response to the first operation command.

In some examples, the memory controller 106 is further configured to sum the first read voltage and the voltage offset value to obtain a second read voltage; and the memory device 104 is configured to perform a read retry operation with the second read voltage.

According to some aspects of examples of the present disclosure, FIG. 20 provides a method for controlling a memory system 102, which comprises: performing a read operation with a first read voltage corresponding to a first data state of a memory cell; obtaining the first number of memory cells with a threshold voltage being less than or equal to the first read voltage, and obtaining the second number of memory cells with a threshold voltage being greater than the first read voltage; determining a difference between the second number and the first number; and acquiring a voltage offset value from a mapping table according to the difference.

In some examples, the mapping table comprises a first mapping table which stores a first interval of values and voltage offset values corresponding to the first interval of values; and the acquiring the voltage offset value from the mapping table according to the difference comprises: multiplying the difference by an association coefficient to obtain a feature value; and in response to the feature value being within the first interval of values, acquiring the voltage offset value corresponding to the first interval of values according to the first mapping table.

In some examples, each memory cell is configured to store one of a plurality of data states; and the association coefficient corresponds to a data state, and association coefficients corresponding to different data states are not equal.

In some examples, the plurality of data states comprise 2ⁿ data states, and each data state of the plurality of data states is distinguished with 2ⁿ−1 read voltages; and a sum of a feature value corresponding to the ith read voltage and a feature value corresponding to the (2ⁿ−i)th read voltage is zero, wherein n is an integer greater than 1, i is a positive integer less than 2ⁿ−1, and i is not equal to 2ⁿ−i.

In some examples, the first mapping table stores a first interval of values for the first data state and stores voltage offset values corresponding to the first interval of values; and the voltage offset values are stored in the first mapping table in order of magnitude.

In some examples, the 2ⁿ−1 read voltages are divided into a plurality of groups; one first mapping table stores a first interval of values of one group of read voltages, and one first interval of values corresponds to voltage offset values for the group; voltage offset values for the read voltage for the highest data state in the group are stored in order of magnitude; and the control method further comprises: performing a read operation with a first read voltage corresponding to the highest data state in the group; and in response to the feature value being within the first interval of values, acquiring a voltage offset value for the group corresponding to the first interval of values.

In some examples, a linear relationship exits between at least part of voltage offset values corresponding to the read voltage for the highest data state in the group and at least part of voltage offset values corresponding to read voltages for other data states in the group.

In some examples, the mapping table comprises a second mapping table which comprises a second interval of values and voltage offset values corresponding to the second interval of values; and the acquiring the voltage offset value from the mapping table according to the difference comprises: in response to the difference being within the second interval of values, acquiring the voltage offset value corresponding to the second interval of values according to the second mapping table.

In some examples, the control method further comprises: sending, by the memory controller 106, a first operation command to the memory device 104; and enabling, by the memory device 104, a single level read operation mode in response to the first operation command.

In some examples, the control method further comprises: summing, by a memory controller 106, the first read voltage and the voltage offset value to obtain a second read voltage; and performing, by a memory device 104, a read retry operation with the second read voltage.

According to some aspects of examples of the present disclosure, there is provided a readable storage medium storing a computer program which, when executed, implements the control method of the memory system 102.

The memory device 104 may comprise a NAND memory, and the memory cell of the NAND memory may either comprise a floating gate memory cell that comprises a floating gate transistor, or a charge trapping memory cell that comprises a charge trapping transistor.

The storage medium may be a Ferromagnetic Random Access Memory (FRAM), a Magnetic Random Access Memory (MRAM), a Read Only Memory (ROM), a Programmable Read-Only Memory (PROM), an Erasable Programmable Read-Only Memory (EPROM), an Electrically Erasable Programmable Read-Only Memory (EEPROM), a Flash Memory, a magnetic surface memory, an optical disk, a Compact Disc Read-Only Memory (CD-ROM), and or other memories; and may also be various apparatuses comprising any one or any combination of the above memory devices 104.

In some examples, an executable instruction may be compiled in any form of programming language (comprising a compiling or interpreting language, or a declarative or procedural language) by adopting a form of a program, a software, a software module, a script or a code; and it may be deployed in any form, comprising deployed as an independent program or as a module, a component, a subroutine, or other units suitable for use in a computing environment.

As an example, the executable instruction may, but does not necessarily, correspond to files in a file system, may be stored in part of a file storing other programs or data, for example, stored in one or more scripts in a Hyper Text Markup Language (HTML) document, stored in a single file dedicated for the discussed program, or stored in a plurality of cooperative files (e.g., the file for storing one or more modules, subprograms or code portions).

As an example, the executable instruction may be deployed on an electronic apparatus for execution, or on a plurality of electronic apparatuses at one site for execution, or distributed on a plurality of electronic apparatuses interconnected through a communication network at a plurality of sites for execution.

According to some aspects of examples of the present disclosure, a memory controller is provided. The memory controller is configured to: control a memory device to perform a read operation with a first read voltage corresponding to a first data state of a memory cell; obtain the first number of memory cells with a threshold voltage being less than or equal to the first read voltage, and obtain the second number of memory cells with a threshold voltage being greater than the first read voltage; determine a difference between the second number and the first number; and acquire a voltage offset value from a mapping table according to the difference.

In some examples, the mapping table comprises a first mapping table which stores a first interval of values and voltage offset values corresponding to the first interval of values; and the memory controller is configured to: multiply the difference by an association coefficient to obtain a feature value; and in response to the feature value being within the first interval of values, acquire the voltage offset value corresponding to the first interval of values according to the first mapping table.

In some examples, each memory cell in the memory device is configured to store one of a plurality of data states; and the association coefficient corresponds to a data state, and association coefficients corresponding to different data states are not equal.

In some examples, the plurality of data states comprise 2ⁿ data states, and each data state of the plurality of data states is distinguished with 2ⁿ−1 read voltages; and a sum of a feature value corresponding to the ith read voltage and a feature value corresponding to the (2ⁿ−i)th read voltage is zero, wherein n is an integer greater than 1, i is a positive integer less than 2ⁿ−1, and i is not equal to 2ⁿ−i.

In some examples, the first mapping table stores a first interval of values for the first data state and stores voltage offset values corresponding to the first interval of values; and the voltage offset values are stored in the first mapping table in order of magnitude.

In some examples, the 2ⁿ−1 read voltages are divided into a plurality of groups; one first mapping table stores a first interval of values corresponding to one group of read voltages, and one first interval of values corresponds to voltage offset values for the group; voltage offset values for the read voltage for the highest data state in the group are stored in order of magnitude; and the memory controller is further configured to: perform a read operation with a first read voltage corresponding to the highest data state in the group; and in response to the feature value being within the first interval of values, acquire a voltage offset value for the group corresponding to the first interval of values.

In some examples, a linear relationship exits between at least part of voltage offset values corresponding to the read voltage for the highest data state in the group and at least part of voltage offset values corresponding to read voltages for other data states in the group.

In some examples, the mapping table comprises a second mapping table which comprises a second interval of values and voltage offset values corresponding to the second interval of values; and the memory controller is configured to: in response to the difference being within the second interval of values, acquire the voltage offset value corresponding to the second interval of values according to the second mapping table.

In some examples, the memory controller is configured to: enable a single level read operation mode, and control the memory device to perform a single level read operation with the first read voltage.

In some examples, the memory controller is further configured to sum the first read voltage and the voltage offset value to obtain a second read voltage.

According to some aspects of examples of the present disclosure, a memory system is provided, the memory system comprises: a memory device; and a memory controller coupled with the memory device, wherein the memory device comprises a plurality of memory cells, and the plurality of memory cells are configured to store one of a plurality of data states; and the memory controller is configured to: control the memory device to perform a read operation with a first read voltage corresponding to a first data state of the plurality of data states; obtain the first number of memory cells with a threshold voltage being less than or equal to the first read voltage, and obtain the second number of memory cells with a threshold voltage being greater than the first read voltage; determine a difference between the second number and the first number; and acquire a voltage offset value from a mapping table according to the difference.

In some examples, the mapping table comprises a first mapping table which stores a first interval of values and voltage offset values corresponding to the first interval of values; and the memory controller is configured to: multiply the difference by an association coefficient to obtain a feature value; and in response to the feature value being within the first interval of values, acquire the voltage offset value corresponding to the first interval of values according to the first mapping table.

In some examples, the association coefficient corresponds to a data state, and association coefficients corresponding to different data states are not equal.

In some examples, the plurality of data states comprise 2ⁿ data states, and each data state of the plurality of data states is distinguished with 2ⁿ−1 read voltages; and a sum of a feature value corresponding to the ith read voltage and a feature value corresponding to the (2ⁿ−i)th read voltage is zero, wherein n is an integer greater than 1, i is a positive integer less than 2ⁿ−1, and i is not equal to 2ⁿ−i.

In some examples, the first mapping table stores a first interval of values for the first data state and stores voltage offset values corresponding to the first interval of values; and the voltage offset values are stored in the first mapping table in order of magnitude.

In some examples, the 2ⁿ−1 read voltages are divided into a plurality of groups; one first mapping table stores a first interval of values corresponding to one group of read voltages, and one first interval of values corresponds to voltage offset values for the group; voltage offset values for the read voltage for the highest data state in the group are stored in order of magnitude; and the memory controller is further configured to: perform a read operation with a first read voltage corresponding to the highest data state in the group; and in response to the feature value being within the first interval of values, acquire a voltage offset value for the group corresponding to the first interval of values.

In some examples, a linear relationship exits between at least part of voltage offset values corresponding to the read voltage for the highest data state in the group and at least part of voltage offset values corresponding to read voltages for other data states in the group.

In some examples, the mapping table comprises a second mapping table which comprises a second interval of values and voltage offset values corresponding to the second interval of values; and the memory controller is configured to: in response to the difference being within the second interval of values, acquire the voltage offset value corresponding to the second interval of values according to the second mapping table.

In some examples, the memory controller is further configured to: send a first operation command to the memory device; and the memory device is configured to: enable a single level read operation mode in response to the first operation command.

In some examples, the memory controller is further configured to sum the first read voltage and the voltage offset value to obtain a second read voltage; and the memory device is configured to perform a read retry operation with the second read voltage.

According to some aspects of examples of the present disclosure, a method for controlling a memory system is provided, which comprises:

performing a read operation with a first read voltage corresponding to a first data state of a memory cell; obtaining the first number of memory cells with a threshold voltage being less than or equal to the first read voltage, and obtaining the second number of memory cells with a threshold voltage being greater than the first read voltage; determining a difference between the second number and the first number; and acquiring a voltage offset value from a mapping table according to the difference.

In some examples, the mapping table comprises a first mapping table which stores a first interval of values and voltage offset values corresponding to the first interval of values; and the acquiring the voltage offset value from the mapping table according to the difference comprises: multiplying the difference by an association coefficient to obtain a feature value; and in response to the feature value being within the first interval of values, acquiring the voltage offset value corresponding to the first interval of values according to the first mapping table.

In some examples, each memory cell is configured to store one of a plurality of data states; and the association coefficient corresponds to a data state, and association coefficients corresponding to different data states are not equal.

In some examples, the plurality of data states comprise 2ⁿ data states, and each data state of the plurality of data states is distinguished with 2ⁿ−1 read voltages; and a sum of a feature value corresponding to the ith read voltage and a feature value corresponding to the (2ⁿ−i)th read voltage is zero, wherein n is an integer greater than 1, i is a positive integer less than 2ⁿ−1, and i is not equal to 2ⁿ−i.

In some examples, the first mapping table stores a first interval of values for the first data state and stores voltage offset values corresponding to the first interval of values; and the voltage offset values are stored in the first mapping table in order of magnitude.

In some examples, the 2ⁿ−1 read voltages are divided into a plurality of groups; one first mapping table stores a first interval of values of one group of read voltages, and one first interval of values corresponds to voltage offset values for the group; voltage offset values for the read voltage for the highest data state in the group are stored in order of magnitude; and the control method further comprises: performing a read operation with a first read voltage corresponding to the highest data state in the group; and in response to the feature value being within the first interval of values, acquiring a voltage offset value for the group corresponding to the first interval of values.

In some examples, a linear relationship exits between at least part of voltage offset values corresponding to the read voltage for the highest data state in the group and at least part of voltage offset values corresponding to read voltages for other data states in the group.

In some examples, the mapping table comprises a second mapping table which comprises a second interval of values and voltage offset values corresponding to the second interval of values; and the acquiring the voltage offset value from the mapping table according to the difference comprises: in response to the difference being within the second interval of values, acquiring the voltage offset value corresponding to the second interval of values according to the second mapping table.

In some examples, the control method further comprises: sending, by a memory controller, a first operation command to a memory device; and enabling, by the memory device, a single level read operation mode in response to the first operation command.

In some examples, the control method further comprises: summing, by a memory controller, the first read voltage and the voltage offset value to obtain a second read voltage; and performing, by a memory device, a read retry operation with the second read voltage.

According to some aspects of examples of the present disclosure, a readable storage medium is provided, the readable storage medium storing a computer program which, when executed, implements the control method.

Examples of the present disclosure provide a memory controller, configured to: control a memory device to perform a read operation with a first read voltage corresponding to a first data state of a memory cell, obtain the first number of memory cells with a threshold voltage being less than or equal to the first read voltage, and obtain the second number of memory cells with a threshold voltage being greater than the first read voltage; and acquire a voltage offset value from a related mapping table according to a difference between the second number and the first number, and sum the voltage offset value and the first read voltage to obtain a second read voltage to perform a read retry operation, to correct a read error of the first read voltage, such that an access time of the related mapping table is reduced, an operation rate of the device is increased, and user experience is optimized.

The above descriptions are merely example implementations of the present disclosure, and the scope of protection of the present disclosure is not limited thereby. Any variations or replacements readily conceivable to a person familiar with the existing technology within the technical scope disclosed by the present disclosure shall fall within the scope of protection of the present disclosure.

What is claimed is:

1. A memory controller, comprising:
a data buffer; and
a control circuit coupled to the data buffer, and wherein the control circuit is configured to:
control a memory device to perform a read operation with a first read voltage corresponding to a first data state of a memory cell;
obtain a first number of memory cells with a threshold voltage being less than or equal to the first read voltage, and obtain a second number of memory cells with a threshold voltage being greater than the first read voltage;
determine a difference between the second number and the first number; and
acquire a voltage offset value from a mapping table according to the difference.

2. The memory controller of claim 1, wherein the mapping table includes a first mapping table which stores a first interval of values and voltage offset values corresponding to the first interval of values; and the memory controller is configured to:
multiply the difference by an association coefficient to obtain a feature value; and
in response to the feature value being within the first interval of values, acquire the voltage offset value corresponding to the first interval of values according to the first mapping table.

3. The memory controller of claim 2, wherein each memory cell in the memory device is configured to store one of a plurality of data states, and the association coefficient corresponds to a data state, and association coefficients corresponding to different data states are not equal.

4. The memory controller of claim 3, wherein
the plurality of data states include 2ⁿ data states, and each data state of the plurality of data states is distinguished with 2ⁿ−1 read voltages; and a sum of a feature value corresponding to the ith read voltage and a feature value corresponding to the (2ⁿ−i)th read voltage is zero, wherein n is an integer greater than 1, i is a positive integer less than 2ⁿ−1, and i is not equal to 2ⁿ−i.

5. The memory controller of claim 4, wherein the first mapping table stores a first interval of values for the first data state and stores voltage offset values corresponding to the first interval of values, and the voltage offset values are stored in the first mapping table in order of magnitude.

6. The memory controller of claim 4, wherein the 2ⁿ−1 read voltages are divided into a plurality of groups; one first mapping table stores a first interval of values corresponding to one group of read voltages, and one first interval of values corresponds to voltage offset values for the group; voltage offset values for the read voltage for the highest data state in the group are stored in order of magnitude; and the memory controller is further configured to:
perform a read operation with a first read voltage corresponding to the highest data state in the group; and
in response to the feature value being within the first interval of values, acquire a voltage offset value for the group corresponding to the first interval of values.

7. The memory controller of claim 6, wherein a linear relationship exits between at least part of voltage offset values corresponding to the read voltage for the highest data state in the group and at least part of voltage offset values corresponding to read voltages for other data states in the group.

8. The memory controller of claim 1, wherein the mapping table includes a second mapping table which includes a second interval of values and voltage offset values corresponding to the second interval of values; and the memory controller is configured to:
in response to the difference being within the second interval of values, acquire the voltage offset value corresponding to the second interval of values according to the second mapping table.

9. The memory controller of claim 1, wherein the memory controller is configured to:
enable a single level read operation mode, and control the memory device to perform a single level read operation with the first read voltage.

10. The memory controller of claim 1, wherein the memory controller is further configured to:
sum the first read voltage and the voltage offset value to obtain a second read voltage.

11. A memory system, comprising:
a memory device including a plurality of memory cells, each of the plurality of memory cells being configured to store one of a plurality of data states; and
a memory controller coupled with the memory device and configured to:
control the memory device to perform a read operation with a first read voltage corresponding to a first data state of the plurality of data states;
obtain the first number of memory cells with a threshold voltage being less than or equal to the first read voltage, and obtain a second number of memory cells with a threshold voltage being greater than the first read voltage;
determine a difference between the second number and a first number; and
acquire a voltage offset value from a mapping table according to the difference.

12. The memory system of claim 11, wherein the mapping table includes a first mapping table which stores a first interval of values and voltage offset values corresponding to the first interval of values; and the memory controller is configured to:
multiply the difference by an association coefficient to obtain a feature value; and
in response to the feature value being within the first interval of values, acquire the voltage offset value corresponding to the first interval of values according to the first mapping table.

13. The memory system of claim 12, wherein the association coefficient corresponds to a data state, and association coefficients corresponding to different data states are not equal.

14. The memory system of claim 13, wherein the plurality of data states include 2ⁿ data states, and each data state of the plurality of data states is distinguished with 2ⁿ−1 read voltages; and a sum of a feature value corresponding to the ith read voltage and a feature value corresponding to the (2ⁿ−i)th read voltage is zero, wherein n is an integer greater than 1, i is a positive integer less than 2ⁿ−1, and i is not equal to 2ⁿ−i.

15. The memory system of claim 14, wherein the first mapping table stores a first interval of values for the first data state and stores voltage offset values corresponding to the first interval of values, and the voltage offset values are stored in the first mapping table in order of magnitude.

16. The memory system of claim 14, wherein the 2ⁿ−1 read voltages are divided into a plurality of groups; one first mapping table stores a first interval of values corresponding to one group of read voltages, and one first interval of values corresponds to voltage offset values for the group, voltage offset values for the read voltage for the highest data state in the group are stored in order of magnitude; and the memory controller is further configured to:
perform a read operation with a first read voltage corresponding to the highest data state in the group; and
in response to the feature value being within the first interval of values, acquire a voltage offset value for the group corresponding to the first interval of values.

17. The memory system of claim 16, wherein a linear relationship exits between at least part of voltage offset values corresponding to the read voltage for the highest data state in the group and at least part of voltage offset values corresponding to read voltages for other data states in the group.

18. The memory system of claim 11, wherein the mapping table includes a second mapping table which includes a second interval of values and voltage offset values corresponding to the second interval of values; and the memory controller is configured to:
in response to the difference being within the second interval of values, acquire the voltage offset value corresponding to the second interval of values according to the second mapping table.

19. The memory system of claim 11, wherein the memory controller is further configured to:
send a first operation command to the memory device; and
the memory device is configured to: enable a single level read operation mode in response to the first operation command.

20. A method for controlling a memory system, comprising:
performing a read operation with a first read voltage corresponding to a first data state of a memory cell;
obtaining a first number of memory cells with a threshold voltage being less than or equal to the first read voltage, and obtaining a second number of memory cells with a threshold voltage being greater than the first read voltage;
determining a difference between the second number and the first number; and
acquiring a voltage offset value from a mapping table according to the difference.
